(19) United States
(12) Patent Application Publication
(10) Pub. No.: US 2023/0064415 A1
(43) Pub. Date: Mar. 2, 2023

(54) SEMICONDUCTOR DEVICE WITH C-SHAPED CHANNEL PORTION, METHOD OF MANUFACTURING THE SAME, AND ELECTRONIC APPARATUS INCLUDING THE SAME

(71) Applicant: Institute of Microelectronics, Chinese Academy of Sciences, Beijing (CN)

(72) Inventor: Huilong Zhu, Poughkeepsie, NY (US)

(21) Appl. No.: 17/759,226

(22) PCT Filed: Dec. 25, 2020
(86) PCT No.: PCT/CN2020/139254

§ 371 Date: Jul. 21, 2022

(30) Foreign Application Priority Data
Jan. 21, 2020 (CN) 202010072920.X
Jan. 21, 2020 (CN) 202010073094.0
May 22, 2020 (CN) 202010445827.9

(51) Int. Cl. H01L 29/06; H01L 29/786; H01L 29/423; H01L 29/08; H01L 29/775; H01L 29/66; H01L 21/8234

(52) U.S. Cl. CPC H01L 29/0673; H01L 29/78696; H01L 29/42392; H01L 29/0847; H01L 29/775; H01L 29/66439; H01L 21/823412; H01L 21/823418

(57) ABSTRACT

A semiconductor device with a C-shaped channel portion, a method of manufacturing the semiconductor device, and an electronic apparatus including the semiconductor device are provided. The semiconductor device may include: a channel portion on a substrate, wherein the channel portion includes a curved nanosheet/nanowire with a C-shaped cross section; source/drain portions respectively located at upper and lower ends of the channel portion with respect to the substrate; and a gate stack surrounding a periphery of the channel portion.

### CROSS-REFERENCE TO RELATED APPLICATION

This application claims priority to Chinese Application No. 202010072920.X, filed on Jan. 21, 2020, entitled “SEMICONDUCTOR DEVICE WITH C-SHAPED CHANNEL PORTION, METHOD OF MANUFACTURING THE SAME, AND ELECTRONIC APPARATUS INCLUDING THE SAME”, claims priority to Chinese Application No. 202010073094.0, filed on Jan. 21, 2020, entitled “SEMICONDUCTOR DEVICE WITH C-SHAPED CHANNEL PORTION, METHOD OF MANUFACTURING THE SAME, AND ELECTRONIC APPARATUS INCLUDING THE SAME”, and claims priority to Chinese Application No. 202010445827.9 filed on May 22, 2020, entitled “SEMICONDUCTOR DEVICE WITH C-SHAPED CHANNEL PORTION, METHOD OF MANUFACTURING THE SAME, AND ELECTRONIC APPARATUS INCLUDING THE SAME”, the contents of which are incorporated herein by reference in their entirety.

### TECHNICAL FIELD

The present disclosure relates to a field of semiconductor, and in particular to a semiconductor device with a C-shaped nanowire/nanosheet channel portion, a method of manufacturing the same, and an electronic apparatus including such semiconductor device.

### BACKGROUND

With the continuous miniaturization of semiconductor devices, devices with various structures such as fin field effect transistors (FinFET), multi-bridge channel field effect transistors (MBCFET), and the like have been proposed. However, the improvements of the devices in terms of increasing the integration density and enhancing the device performance due to the limitation of the device structure still may not meet the requirements.

In addition, it is difficult for vertical nanosheet/nanowire devices such as metal oxide semiconductor field effect transistors (MOSFETs) to control thicknesses or diameters of the nanosheets/nanowires due to process fluctuations such as lithography, etching and the like.

### SUMMARY

In view of this, the purpose of the present disclosure is at least partially to provide a semiconductor device with a C-shaped nanowire/nanosheet channel portion, a method of manufacturing the same, and an electronic apparatus including such semiconductor device.

According to an aspect of the present disclosure, a semiconductor device is provided, including: a channel portion on a substrate, wherein the channel portion includes a curved nanosheet/nanowire with a C-shaped cross section; source/drain portions respectively located at upper and lower ends of the channel portion with respect to the substrate; and a gate stack surrounding a periphery of the channel portion. According to the embodiments, the channel portion may include a plurality of the curved nanosheets/nanowires that are sequentially stacked in a lateral direction with respect to the substrate, and a cross section of each of the plurality of the curved nanosheets/nanowires has a C-shaped cross section.

According to another aspect of the present disclosure, A method of manufacturing a semiconductor, including: providing a stack of a first material layer, a second material layer and a third material layer; patterning the stack into a ridge-like structure, wherein the ridge-like structure includes a first side and a second side that are opposite to each other, and a third side and a fourth side that are opposite to each other; concaving a sidewall of the second material layer laterally with respect to a sidewall of the first material layer and a sidewall of the third material layer on the third side and the fourth side, so as to form a first concave portion; forming a first position retaining layer in the first concave portion; concaving a sidewall of the second material layer laterally with respect to a sidewall of the first material layer and a sidewall of the third material layer on the first side and the second side, so as to form a second concave portion; forming at least a first channel layer on a surface of the second material layer exposed by the second concave portion; forming a second position retaining layer in a remaining space of the second concave portion; forming source/drain portions in the first material layer and the third material layer; forming a strip-like opening in the ridge-like structure, so as to divide the ridge-like structure into two parts respectively located on the first side and the second side; removing the second material layer by the opening to expose the first channel layer, so as to define a third concave portion; forming a third position retaining layer in the third concave portion; forming an isolation layer on the substrate, wherein a top surface of the isolation layer is not lower than a top surface of the first material layer and not higher than a bottom surface of the third material layer; removing the first position retaining layer, the second position retaining layer and the third position retaining layer; and forming a gate stack surrounding the channel layer on the isolation layer, wherein the gate stack includes parts embedded into spaces left due to the removal of the first position retaining layer, the second position retaining layer and the third position retaining layer. According to the embodiments, a single or a plurality of channel layers may be formed. For example, a single channel layer, that is, the first channel layer may be formed on the surface of the second material layer exposed by the second concave portion. In case of a plurality of channel layers, the plurality of channel layers may be formed on the surface of the second material layer exposed by the second concave portion, or one or more channel layers may be formed on the surface of the second material layer exposed by the second concave portion, and other channel layers may be formed on the surface exposed by the third concave portion.

According to another aspect of the present disclosure, an electronic apparatus including the semiconductor device as described above is provided.

According to the embodiments of the present disclosure, a semiconductor device with a new structure is provided, having advantages of high performance and high density.

### BRIEF DESCRIPTION OF THE DRAWINGS

The above and other obj ectives, features and advantages of the present disclosure will become more apparent from the following descriptions of the embodiments of the present disclosure with reference to the accompanying drawings, in which:

FIGS. 1 to 22 schematically illustrate some stages in a process of manufacturing a semiconductor device according to an embodiment of the present disclosure;

FIGS. 23(a) to 36 schematically illustrate some stages in a process of manufacturing a semiconductor device according to another embodiment of the present disclosure; and

FIGS. 37 and 38 schematically illustrate some stages in a process of manufacturing a semiconductor device according to another embodiment of the present disclosure, wherein:

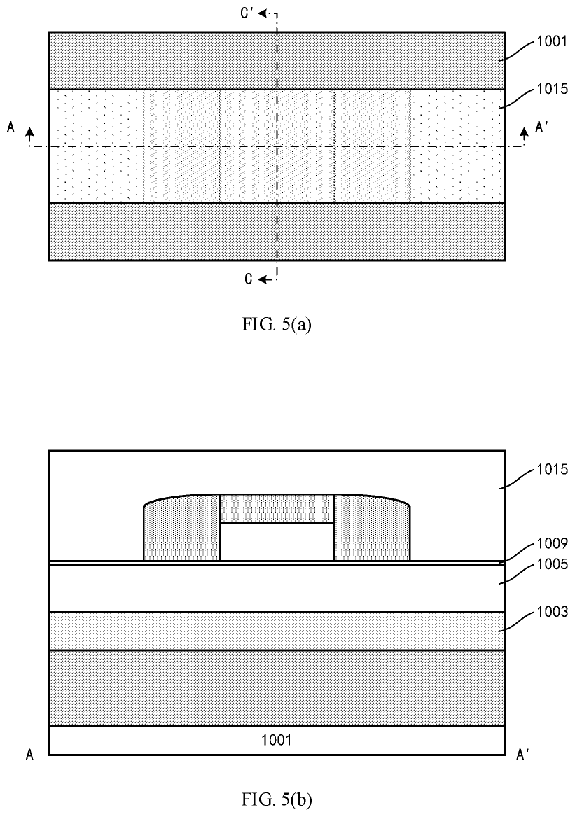

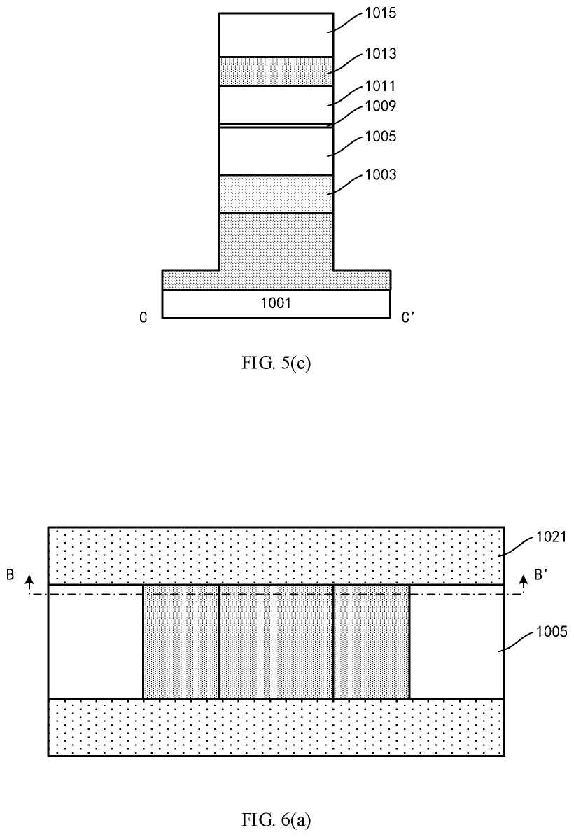

FIGS. 5(a), 6(a), 18(a), 19, 20(a), 21(a), 22, 32(a), 33, 34(a), 35(a), 36 are top views

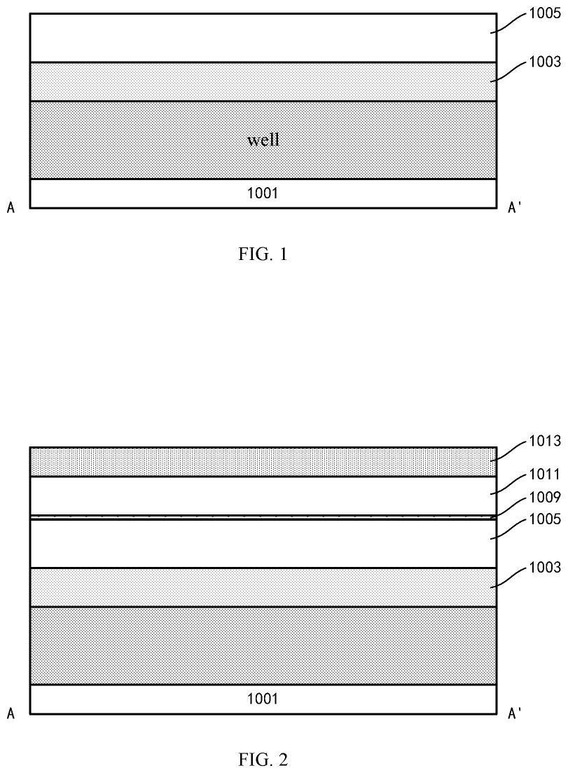

FIGS. 1 to 4, 5(b), 6(b), 7 to 13, 14(a), 14(b), 15, 16(a), 17, 18(b), 20(b), 21(b), 23(a), 23(b), 24, 25, 26, 27(a), 27(b), 28, 29, 30(a), 31, 32(b), 34(b), 35(b) are sectional views taken along line AA';

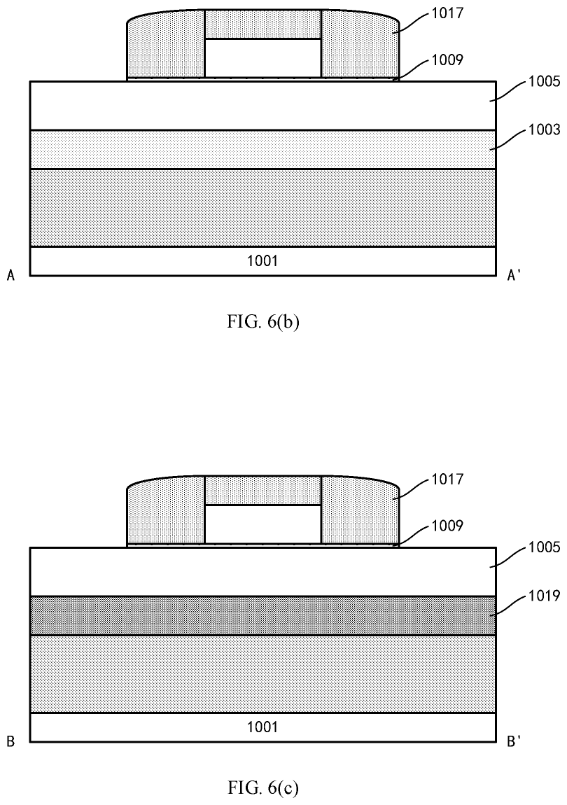

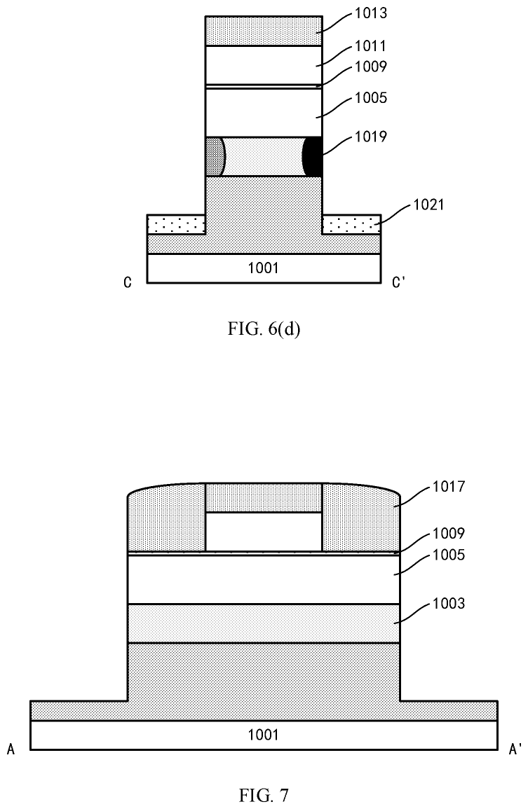

FIG. 6(c) is a cross-sectional view taken along line BB′;

FIGS. 5(c) and 6(d) are cross-sectional views taken along line CC′;

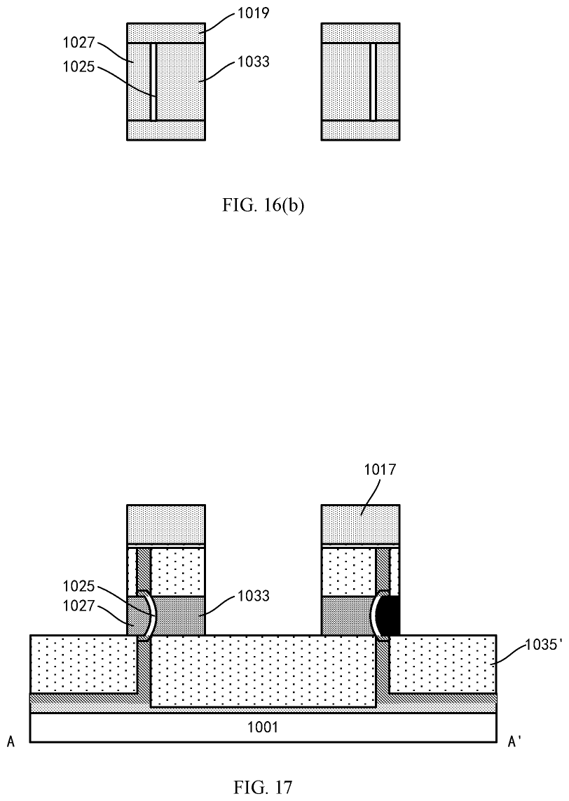

FIGS. 16(b), 18(c), 20(c), 30(b), 32(c), 34(c), 37, 38 are cross-sectional views taken along line DD′ in FIG. 16(a).

Throughout the drawings, the same or similar reference numerals indicate the same or similar components.

### DETAILED DESCRIPTION OF EMBODIMENTS

In the following, the embodiments of the present disclosure will be described with reference to the accompanying drawings. However, it should be understood that these descriptions are exemplary only, and are not intended to limit the scope of the present disclosure. In addition, in the following descriptions, descriptions of well-known structures and techniques are omitted to avoid unnecessarily obscuring the concept of the present disclosure.

Various structural schematic diagrams according to embodiments of the present disclosure are shown in the accompanying drawings. The figures are not to scale, some details have been exaggerated for clarity, and some details may have been omitted. The shapes of the various regions and layers shown in the figures, as well as their relative sizes and positional relationships are only exemplary, and may vary in practice due to manufacturing tolerances or technical limitations, and those skilled in the art will Regions/layers with different shapes, sizes, relative positions may be additionally designed as desired.

In the context of this disclosure, when a layer/element is referred to as being “on” another layer/element, it may be directly on the other layer/element or intervening layers/elements may be present therebetween. In addition, if a layer/element is “on” another layer/element in one orientation, the layer/element may be “under” the other layer/element when the orientation is reversed.

According to embodiments of the present disclosure, there is provided a vertical semiconductor device having an active region disposed vertically on a substrate (e.g., in a direction substantially perpendicular to a surface of the substrate). A channel portion may be a curved nanosheet/nanowire with a C-shaped cross section (e.g., a cross section perpendicular to the substrate surface), thus, such a device may be referred to as a C-Channel FET (CCFET). There may be one or more curved nanosheets/nanowires in the channel portion. In the case of a plurality of curved nanosheets/nanowires, the curved nanosheets/nanowires may be stacked one by one in a lateral direction (e.g., a direction substantially parallel to the substrate surface) relative to the substrate. As described below, the nanosheets/nanowires may be formed by epitaxial growth, and thus may be an integral monolith, and may have a substantially uniform thickness.

In the case of a plurality of curved nanosheets/nanowires, at least some of the nanosheets/nanowires may have different properties to optimize device performance. For example, the plurality of nanosheets/nanowires may include a first nanosheet/nanowire and a second nanosheet/nanowire located on two sides of the channel portion in the lateral direction, respectively, and a third nanosheet/nanowire located between the first nanosheet/nanowire and the second nanosheet/nanowire. The first nanosheet/nanowire and the second nanosheet/nanowire may have an improved interface quality with a gate stack, while the third nanosheet/nanowire may have a high carrier mobility. Additionally or alternatively, the first nanosheet/nanowire and the second nanosheet/nanowire may have a high carrier mobility, while the third nanosheet/nanowire may optimize a carrier distribution. Additionally or alternatively, the third nanosheet/nanowire may be used to limit carriers in the first nanosheet/nanowire and/or the second nanosheet/nanowire. For example, for an n-type device, a lowest energy level of a conduction band of the third nanosheet/nanowire may be higher than a lowest energy level of a conduction band of the first nanosheet/nanowire and/or the second nanosheet/nanowire; for a p-type device, a highest energy level of a valence band of the third nanosheet/nanowire may be lower than a highest energy level of a valence band of the first nanosheet/nanowire and/or the second nanosheet/nanowire.

The semiconductor device may further include source/drain portions disposed at upper and lower ends of the channel portion, respectively. Sizes of the source/drain portions in the lateral direction relative to the substrate may be larger than a size of the channel portion in the corresponding direction to ensure that the upper and lower ends of the channel portion are connected to the source/drain portions. The source/drain portions may have certain doping. For example, for a p-type device, the source/drain portions may have p-type doping; for an n-type device, the source/drain portions may have n-type doping. The channel portions may have certain doping to adjust a threshold voltage of the device. Alternatively, the semiconductor device may be a junctionless device, wherein the channel portion and the source/drain portions may have doping of a same conductivity type. Alternatively, the semiconductor device may be a tunneling type device in which source/drain portions at two ends of the channel portion may have doping types opposite to each other.

The source/drain portion may be provided in a corresponding semiconductor layer.

For example, the source/drain portion may be a doped region in the corresponding semiconductor layer. The source/drain portion may be a part or all of the corresponding semiconductor layer. In case that the source/drain portion is part of the corresponding semiconductor layer, there may be a doping concentration interface between the source/drain portion and the rest of the corresponding semiconductor layer. As described below, the source/drain portion may be formed by diffusion doping. In this case, the doping concentration interface may be substantially along the vertical direction with respect to the substrate.

The channel portion may include a single crystal semiconductor material. Certainly, the source/drain portion or the semiconductor layer in which the source/drain portion is formed may also include a single crystal semiconductor material. For example, they may all be formed by epitaxial growth.

The semiconductor device may further include a gate stack surrounding a periphery of the channel portion. Accordingly, the semiconductor device according to the embodiments of the present disclosure may be a gate-around device. According to the embodiments of the present disclosure, the gate stack may be self-aligned to the channel portion. For example, at least a part of the gate stack close to the channel portion may be substantially coplanar with the channel portion. For example, the part of the gate stack is substantially coplanar with upper and/or lower surfaces of the channel portion.

Such a semiconductor device may be manufactured, for example, as follows.

According to an embodiment, a stack of a first material layer, a second material layer and a third material layer may be provided on the substrate. The first material layer may be used to define a position of a lower source/drain portion, the second material layer may be used to define a position of the gate stack, and the third material layer may used to define a position of an upper source/drain portion. The first material layer may be provided through a substrate, e.g., an upper part of the substrate, and the second material layer and the third material layer may be sequentially formed on the first material layer by, e.g., epitaxial growth. Alternatively, the first material layer, the second material layer and the third material layer may be sequentially formed on the substrate by, for example, epitaxial growth. The first material layer and the third material layer may be in-situ doped while epitaxially growing to form source/drain portions therein.

The stack may be patterned as a ridge-like structure. The ridge-like structure may include a first side and a second side opposite to each other, and a third side and a fourth side opposite to each other. For example, the ridge-like structure may be quadrilateral (such as a rectangle or a square) in a plan view. The channel portion may be formed on a pair of opposing sidewalls (e.g., a first side and a second side) of the ridge-like structure.

In order to subsequently form the gate stack surrounding the channel portion, a space for forming the gate stack may be defined on the third side and the fourth side of the ridge-like structure. For example, sidewalls of the second material layer may be laterally concaved relative to sidewalls of the first material layer and the third material layer at the third side and the fourth side of the ridge-like structure, thereby defining first concave portions. The first concave portion may have a curved surface concaved toward an inner side of the ridge-like structure. A first position retaining layer may be formed in the first concave portion.

Likewise, sidewalls of the second material layer may be laterally concaved relative to the sidewalls of the first and third material layers at the first and second sides of the ridge-like structure, thereby defining second concave portions to define spaces for the gate stack. The second concave portion may have a curved surface concaved toward an inner side of the ridge-like structure. A channel portion may be formed on a surface of the second concave portion. For example, at least a first channel layer (which may then be used as a channel portion) may be formed by epitaxial growth on an exposed surface of the ridge-like structure. One device may be formed based on the channel layer on the sidewall of the first side and the sidewall of the second side of the ridge-like structure, respectively. Thus, two devices opposite to each other may be formed based on a single ridge-like structure. A second position retaining layer may be formed in the second concave portion having the channel layer formed on the surface thereof.

After defining the second concave portion and before forming the first channel layer, the exposed surface of the ridge-like structure may also be etched back by a certain amount, e.g., approximately a thickness of the first channel layer to be formed. This helps to ensure that the subsequently formed gate stacks have substantially equal gate lengths on two opposite sides of the channel portion.

The source/drain portions may be formed in the first material layer and the third material layer. For example, the source/drain portions may be formed by doping the first material layer and the third material layer (especially in that case that they are undoped when formed). This doping may be achieved by a solid-phase dopant source layer.

An opening may be formed in the ridge-like structure to separate active regions of the two devices. The opening may also extend substantially along the sidewall of the first side or the second side of the ridge-like structure so that the ridge-like structure is divided into two parts on the first side and the second side, respectively.

Through the opening, the second material layer may be removed to expose the first channel layer and thus the third concave portion is defined. If a designed number of channel layers are not formed in the above-described processing of forming at least the first channel layer, at least the second channel layer may be formed on a surface of the first channel layer exposed by the third concave portion to form a total of design number of channel layers. After that, a third position retaining layer may be formed in a remaining space of the third concave portion. Alternatively, the third position retaining layer may be directly formed in the third concave portion if the designed number of channel layers have been formed in the above-mentioned processing of forming at least the first channel layer.

Currently, the first position retaining layer, the second position retaining layer, and the third position retaining layer surround the channel portion. The gate stack surrounding the channel portion may be formed by replacing the first position retaining layer, the second position retaining layer and the third position retaining layer with a gate stack through a replacement gate process.

According to the embodiments of the present disclosure, a thickness and a gate length of the nanosheet/nanowire used as the channel portion are mainly determined by epitaxial growth instead of etching or photolithography, and thus may have good control of the channel size/thickness and the gate length.

The present disclosure may be presented in various forms, and some examples of which will be described below. In the following descriptions, a selection of various materials is involved. The selection of material takes into account an etch selectivity in addition to a function of the material (e.g., a semiconductor material is used to forming an active region, a dielectric material is used to form an electrical isolation). In the following descriptions, a desired etch selectivity may or may not be indicated. It should be clear to those skilled in the art that when it is mentioned below that a certain material layer is etched, if it is not mentioned that other layers are also etched or the drawing does not show that other layers are also etched, such etching may be selective, and the material layer may have etch selectivity relative to other layers exposed to the same etch recipe.

FIGS. 1 to 22 schematically show some stages in a process of manufacturing a semiconductor device according to the embodiments of the present disclosure.

As shown in FIG. 1, a substrate 1001 (an upper part of the substrate may constitute the above-mentioned first material layer) is provided. The substrate 1001 may be various forms of substrates, including but not limited to a bulk semiconductor material substrate such as a bulk Si substrate, a semiconductor-on-insulator (SOI) substrate, a compound semiconductor substrate such as a SiGe substrate, and the like. In the following descriptions, for ease of description, a bulk Si substrate is used as an example for description. Here, a silicon wafer is provided as the substrate 1001.

A well region may be formed in the substrate 1001. If a p-type device is to be formed, the well region may be an n-type well; if an n-type device is to be formed, the well region may be a p-type well. The well region may be formed by, for example, implanting a dopant of a corresponding conductivity type (a p-type dopant such as B or In, or an n-type dopant such as As or P) into the substrate 1001 and then thermal annealing. There are a plurality of ways in the art to provide such well region, which will not be repeated here.

The second material layer 1003 and the third material layer 1005 may be formed on the substrate 1001 by, for example, epitaxial growth. The second material layer 1003 may be used to define the position of the gate stack whose thickness is, for example, about 20 nm-50 nm. The third material layer 1005 may be used to define the position of the upper source/drain portion whose thickness is, for example, about 20 nm-200 nm.

Adjacent ones of the substrate 1001 and the above-mentioned layers formed thereon may have etching selectivity with respect to one another. For example, in case that the substrate 1001 is the silicon wafer, the second material layer 1003 may contain SiGe (e.g., with an atomic percentage of Ge about 10-30 atomic percent), and the third material layer 1005 may contain Si.

According to the embodiment, a spacer pattern transfer technique is used in following patterning process. To form the spacer, a mandrel pattern may be formed. For example, as shown in FIG. 2, a layer 1011 for the mandrel pattern may be formed on the third material layer 1005 by, for example, deposition. For example, the layer 1011 for the mandrel pattern may contain amorphous silicon or polysilicon with a thickness of about 50 nm-150 nm. In addition, for better etching control, an etch stop layer 1009 may be formed first by, for example, deposition. For example, the etch stop layer 1009 may contain an oxide (e.g., silicon oxide) with a thickness of about 1 nm-10 nm.

On the layer 1011 for the mandrel pattern, a hard mask layer 1013 may be formed, by for example, deposition. For example, the hard mask layer 1013 may contain a nitride (e.g., silicon nitride) with a thickness of about 30 nm-100 nm.

The layer 1011 for the mandrel pattern may be patterned into the mandrel pattern.

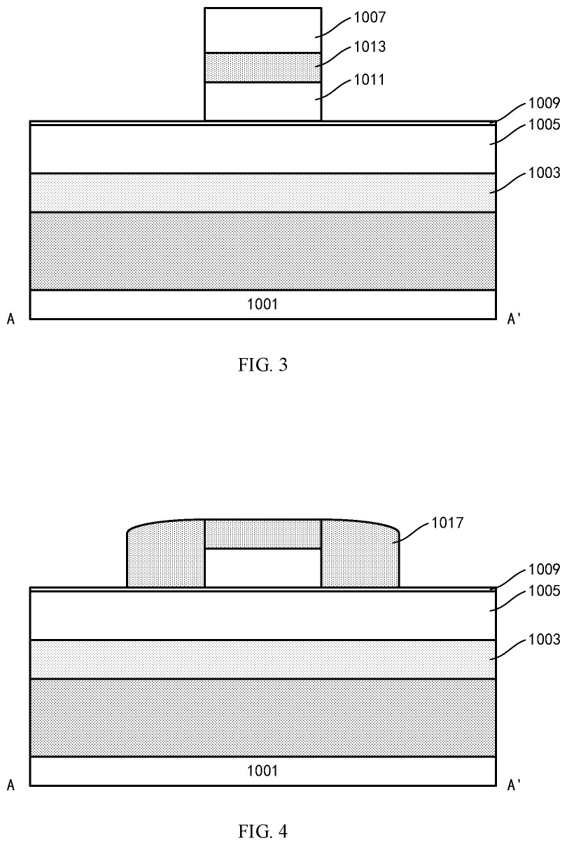

For example, as shown in FIG. 3, a photoresist 1007 may be formed on the hard mask layer 1013 and patterned into a strip extending in a first direction (a direction perpendicular to a paper surface in FIG. 3) by photolithography. By using the photoresist 1007 as an etch mask, the hard mask layer 1013 and the layer 1011 for the mandrel pattern are sequentially selectively etched by, for example, reactive ion etching (ME), and a pattern of the photoresist is transferred to the hard mask layer 1013 and the layer 1011 for the mandrel pattern. The etching may be stopped at the etch stop layer 1009. After that, the photoresist 1007 may be removed.

As shown in FIG. 4, spacers 1017 may be formed on sidewalls on two opposite sides of the mandrel pattern 1011 in a second direction (a horizontal direction in the paper surface in FIG. 4) intersecting with (e.g., perpendicular to) the first direction. For example, a layer of nitride with a thickness of about 10 nm-100 nm may be deposited approximately conformally, and then the deposited nitride layer may be vertically etched by anisotropic etching such as RIE (which may be stopped at the etch stop layer 1009) to remove a lateral extension thereof and leave a vertical extension thereof, thus obtaining the spacers 1017. The spacers 1017 may then be used to define the position of the active region of the device.

The mandrel pattern formed as described above and the spacers 1017 formed on the sidewalls thereof extend in the first direction. A range thereof in the first direction may be defined, thus a range of the active region of the device in the first direction is defined.

As shown in FIGS. 5(a) to 5(c), a photoresist 1015 may be formed on the structure shown in FIG. 4 and patterned by photolithography into a strip occupying a certain range in the first direction, such as extending in the second direction perpendicular to the first direction. The photoresist 1015 may be used as an etch mask, and underlying layers may be selectively etched sequentially by, for example, ME. The etching may proceed into the substrate 1001, especially the well region therein, so to form a recess in the substrate 1001. An isolation such as shallow trench isolation (STI) may then be formed in the formed recess. After that, the photoresist 1015 may be removed.

As shown in FIG. 5(c), sidewalls of the second material layer 1003 in the first direction are currently exposed to the outside.

According to the embodiment of the present disclosure, in order to form a gate stack surrounding the channel portion, spaces for the gate stack may be reserved at two ends of the second material layer in the first direction.

To this end, as shown in FIGS. 6(a) to 6(d), the second material layer 1003 may be selectively etched so that the sidewalls of the second material layer in the first direction are relatively concaved. Atomic layer etching (ALE) may be used to better control an etched amount. For example, the etched amount may be about 5 nm-20 nm. Depending on characteristics of the etching, such as the etching selectivity of the second material layer 1003 with respect to the substrate 1001 and the third material layer 1005, the sidewalls of the second material layer 1003 may exhibit different shapes after the etching. In FIG. 6(d), it is shown that the sidewall of the second material layer 1003 has an inwardly concaved C shape after the etching. However, the present disclosure is not limited to this. For example, when the etching selectivity is good, the sidewall of the second material layer 1003 after the etching may be substantially vertical. Here, the etching may be isotropic, especially when a larger amount of etching is required. In the concave formed as above, a dielectric material may be filled, by deposition and then etching back, to define a space for the gate stack. For example, a dielectric material, such as SiC, which is sufficient to fill the concave, may be deposited on the substrate, and then the deposited dielectric material may be etched back by, for example, ME. In this way, the dielectric material outside the range defined by the hard mask layer 1013 and the spacers 1017 may be removed, and the dielectric material remains in the aforementioned concave to form a first position retaining layer 1019.

According to the embodiment of the present disclosure, a protective layer 1021 may also be formed on the substrate 1001. For example, an oxide layer may be formed on the substrate 1001 by deposition, and the deposited oxide layer may be planarized such as chemical mechanical polishing (CMP) (the CMP may be stopped at the hard mask layer 1013) and etched back to form the protective layer 1021. Here, the protective layer 1021 may be located in the recess of the substrate 1001, and a top surface of the protective layer is lower than a top surface of the substrate 1001. In addition, during the etching back process, a part of the etch stop layer 1009 (which is also an oxide in this example) exposed to the outside may also be etched. According to other embodiments, an operation of forming the protective layer 1021 may be performed before the operation (including the concaving and filling operations) of forming the first position retaining layer 1019.

The protective layer 1021 may protect the surface of the substrate 1001. For example, in the example, the range of the active region in the first direction is first defined. Subsequently, the range of the active region in the second direction is defined. The protective layer 1021 may be used to avoid affecting the surface of the substrate currently exposed in the recess (see FIG. 5(c)) when the range of the active region in the second direction is defined. In addition, in the case where different types of well regions are formed in the substrate 1001, the protective layer 1021 may protect a pn junction between the different types of well regions from being destroyed by the etching (for example, the etch back when forming the first position retaining layer 1019).

As shown in FIG. 7, the third material layer 1005, the second material layer 1003 and the upper part (the first material layer) of the substrate 1001 may be patterned into a ridge-like structure by using the hard mask layer 1013 and the spacers 1017 (in fact, a range of the ridge-like structure in the first direction has been defined by the above processes). For example, the hard mask layer 1013 and the spacers 1017 may be used as an etch mask, and each layer is sequentially selectively etched by, for example, RIE, so as to transfer the pattern to the underlying layers. Thus, the upper part of the substrate 1001, the second material layer 1003 and the third material layer 1005 may form a ridge-like structure. As described above, due to a presence of the protective layer 1021, the etching may not affect parts of the substrate 1001 on two sides of the ridge-like structure in the first direction.

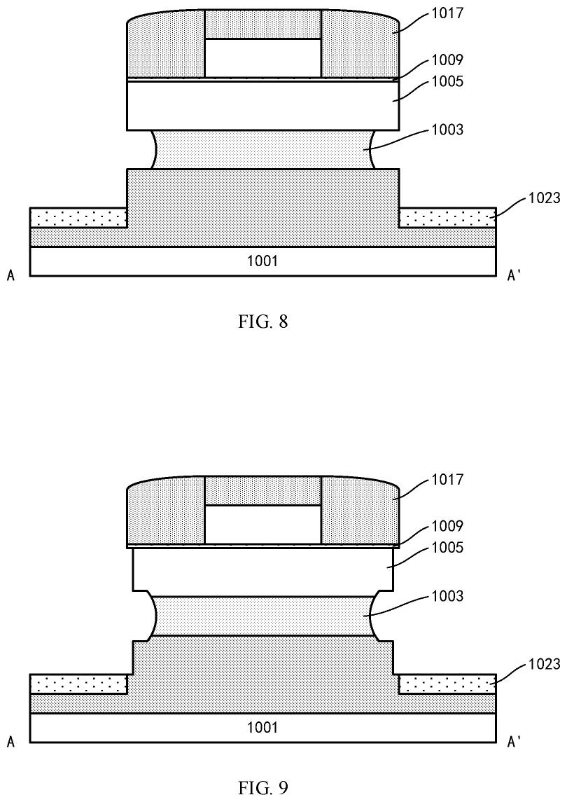

Here, well regions of the substrate 1001 may also be etched. An etched degree of substrate 1001 may be substantially the same as or similar to the etched degree of the substrate 1001 described above in connection with FIGS. 5(a) to 5(c). Likewise, recesses are formed in the substrate 1001. And a protective layer may also be formed in these recesses (see 1023 in FIG. 8).

The protective layer 1023 together with the previous protective layer 1021 surround a periphery of the ridge-like structure. In this way, similar processing conditions may be provided around the ridge-like structure, that is, the recesses are formed in the substrate 1001 and protective layers 1021 and 1023 are formed in the recesses.

Likewise, in order to form the gate stack surrounding the channel portion, spaces for the gate stack may be left on two ends of the second material layer in the second direction. For example, as shown in FIG. 8, the second material layer 1003 may be selectively etched so that sidewalls of the second material layer in the second direction are relatively concaved (spaces for the gate stack may be defined). ALE may be used to better control an etched amount. For example, the etched amount may be about 10 nm-40 nm. As described above, the sidewalls of the second material layer 1003 may have an inwardly concaved C shape after the etching. Here, the etching may be isotropic, especially when a larger amount of etching is required. Generally, the C-shaped sidewalls of the second material layer 1003 have a greater curvature at upper and lower ends, and a smaller curvature at the waist or middle.

A first channel layer may be formed on the sidewalls of the ridge-like structure to subsequently define the channel portion. In order to keep gate lengths (for example, in the direction perpendicular to the substrate surface) of gate stacks be substantially equal to each other when the gate stacks are subsequently formed on the left and right sides of the C-shaped channel portion, as shown in FIG. 9, the ridge-like structure (exposed surfaces of the first material layer, the second material layer and the third material layer) may be etched back such that peripheral sidewalls of the ridge-like structure are laterally concaved relative to the peripheral sidewalls of the spacers 1017. ALE may be used to control an etch depth. The etch depth may be substantially equal to a thickness of the first channel layer that will be subsequently grown. For example, the thickness is about 5 nm-15 nm.

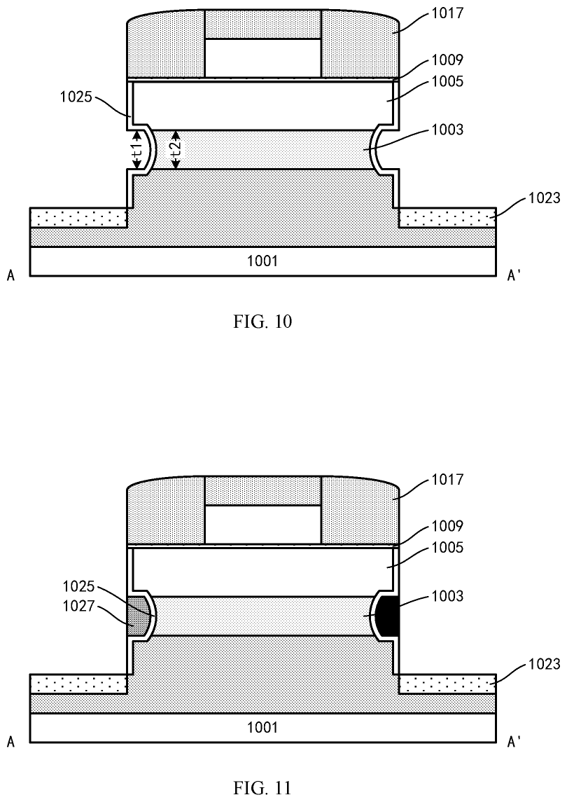

Then, as shown in FIG. 10, the first channel layer 1025 may be formed on the sidewalls of the ridge-like structure by, for example, selective epitaxial growth. Due to the selective epitaxial growth, the first channel layer 1025 may not be formed on a surface of the first position retaining layer 1019. The first channel layer 1025 may then define a channel portion with a thickness of, for example, about 3 nm-15 nm. According to the embodiment of the present disclosure, the thickness of the first channel layer 1025 (which is subsequently used as the channel portion) may be determined through an epitaxial growth process, and thus the thickness of the channel portion may be better controlled. The first channel layer 1025 may be doped in-situ during the epitaxial growth to adjust a threshold voltage of the device.

In FIG. 10, sidewalls of parts of the first channel layer 1025 on the sidewalls of the first material layer and the third material layer are shown to be substantially aligned with sidewalls of the spacers 1017. This may be achieved by controlling the amount of etch back and the thickness of the epitaxial growth to be substantially the same. However, the present disclosure is not limited thereto. For example, the sidewalls of the parts of the first channel layer 1025 on the sidewalls of the first and third material layers may be concaved or even protruded relative to the sidewalls of the spacers 1017.

Here, the above etch-back may be performed to etch upper and lower ends of the concave portion upwardly and downwardly, respectively, so that after the first channel layer 1025 is grown, a height t1 of the concave portion may be substantially the same as a thickness t2 of the second material layer 1003. In this way, the gate stacks subsequently formed on the left and right sides of the first channel layer 1025 may have substantially equal gate lengths. However, the present disclosure is not limited thereto. According to the embodiment of the present disclosure, the gate length outside the first channel layer 1025 may also be changed by adjusting the amount of etch back, thereby changing a ratio of the gate lengths on the two sides, so as to optimize an influence on the device performance due to different topographies on the left and right sides of the C-shaped channel portion.

A material of the first channel layer 1025 may be appropriately selected according to performance requirements of the device. For example, the first channel layer 1025 may contain various semiconductor materials such as Si, Ge, SiGe, InP, GaAs, InGaAs, and the like. In the example, the first channel layer 1025 may contain the same material as the first material layer and the third material layer, such as Si.

In the example of FIG. 10, the first channel layers 1025 on two opposite sides of the ridge-like structure in the second direction may have substantially the same characteristics (e.g., material, dimension, doping characteristics, etc.), and may be symmetrically arranged with each other on the two opposite sides of the second material layer. However, the present disclosure is not limited thereto. As described below, with a single ridge-like structure, two devices opposite to each other may be formed. According to the performance requirements of the two devices, the first channel layers 1025 on the two opposite sides of the ridge-like structure may have different characteristics in, for example, at least one aspect of thickness, material and doping characteristics.

This may be achieved by growing the first channel layer in one device region while shielding the other device region.

Since the second material layer 1003 is concaved, gaps are formed outside a part of the first channel layer 1025 corresponding to the second material layer 1003. The gate stack may then be formed in the gaps. To prevent subsequent processing from leaving an unnecessary material in the gaps or affecting the first channel layer 1025, as shown in FIG. 11, a second position retaining layer 1027 may be formed in the gaps. Likewise, the second position retaining layer 1027 may be formed by deposition and then etch back, and may contain a dielectric material such as SiC. In the example, the first position retaining layer 1019 and the second position retaining layer 1027 contain the same material, so that they may be subsequently removed together by one same etch recipe. However, the present disclosure is not limited to this. For example, they may contain different materials.

After that, source/drain doping may be performed.

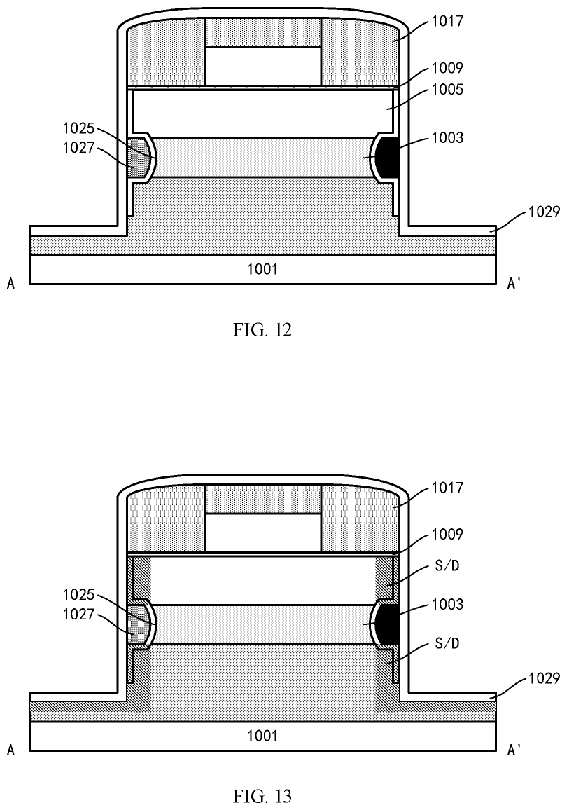

As shown in FIG. 12, a solid phase dopant source layer 1029 may be formed on the structure shown in FIG. 11 by, for example, deposition. The solid phase dopant source layer 1029 may be formed in a substantially conformal manner. For example, the solid phase dopant source layer 1029 may be an oxide containing a dopant, with a thickness of about 1 nm-5 nm. The dopant contained in the solid phase dopant source layer 1029 may be used to dope source/drain portions (and optionally, the exposed surface of the substrate 1001), and thus may have the same conductivity type as the source/drain portions to be formed. For example, for a p-type device, the solid phase dopant source layer 1029 may contain a p-type dopant such as B or In; for an n-type device, the solid phase dopant source layer 1029 may include an n-type dopant such as P or As. A concentration of the dopant of the solid phase dopant source layer 1029 may be about 0.1%-5%.

In the example, before forming the solid phase dopant source layer 1029, the protective layers 1021, 1023 may be selectively etched by, for example, RIE, to expose the surface of the substrate 1001. In this way, the exposed surface of the substrate 1001 may also be doped to form contact regions of each of the source/drain portions S/D at lower ends of the two devices.

As shown in FIG. 13, the dopant in the solid phase dopant source layer 1029 may be driven into the first channel layer, the first material layer and the third material layer by annealing to form the source/drain portions S/D (and optionally, the dopant may be driven into the exposed surface of the substrate 1001 to form the contact regions of each of the source/drain portions S/D at the lower ends of the two devices). After that, the solid phase dopant source layer 1029 may be removed.

Since the first material layer and the third material layer may contain the same material, and the solid phase dopant source layer 1029 may be formed on their surfaces in the substantially conformal manner, degrees of the dopant driven from the solid phase dopant source layer 1029 into the first material layer and the third material layer may be approximately the same. Therefore, (doping concentration) interfaces of the source/drain portions S/D (with inner parts of the first material layer and the third material layer) may be approximately parallel to the surfaces of the first material layer and the third material layer, that is, they may be aligned with each other in a vertical direction.

In the example, the first material layer is provided by the upper part of the substrate 1001. However, the present disclosure is not limited thereto. For example, the first material layer may also be an epitaxial layer on the substrate 1001. In this case, the first material layer and the third material layer may be doped in-situ during epitaxial growth, rather than doped by using the solid phase dopant source layer.

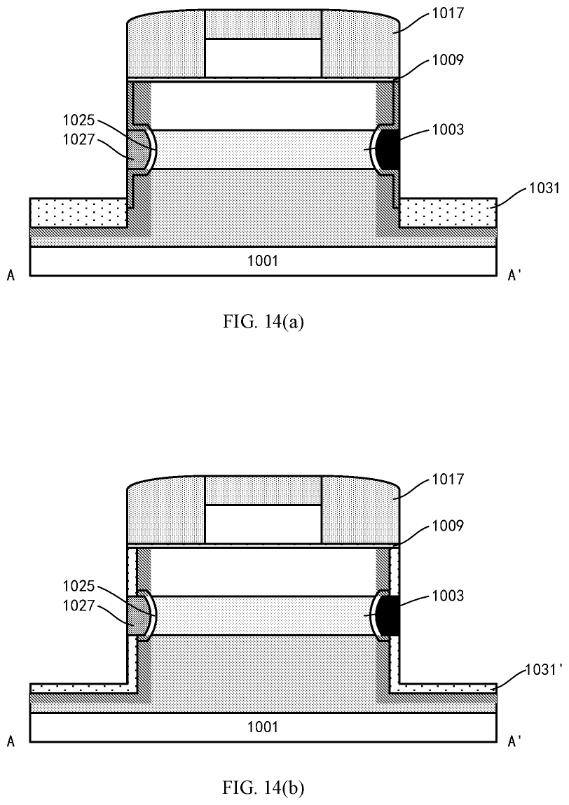

As shown in FIG. 14(a), in the recesses surrounding the ridge-like structure, an isolation layer 1031 may be formed. A method of forming the isolation layer may be similar to the method of forming the protective layers 1021 and 1023 as described above, and the details will not be described here again.

To reduce a capacitance between the gate portion and the source/drain portion, an overlap between the gate portion and the source/drain portion may be further reduced. For example, as shown in FIG. 14(b), after the solid-phase dopant source layer 1029 is removed, the source/drain portion S/D may be further concaved by selective etching, so that the overlap between the source/drain portion S/D and the first position retaining layer 1019(which subsequently defines the position of the gate stack), and the overlap between the source/drain portion S/D and the second position retaining layer 1027 (which subsequently defines the position of the gate stack) are reduced. In the example, when the source/drain portion S/D is further concaved, the parts of the first channel layer 1025 on the sidewalls of the first material layer and the third material layer are removed, so that the first material layer and the third material layer may be further concaved. In gaps formed under the hard mask layer 1013 and the spacer 1017 due to the concave of the source/drain portion S/D, a dielectric 1031′ such as an oxynitride or an oxide may be filled. The filling may be achieved by deposition (and planarization) and then etch back. A certain thickness of the dielectric 1031′ is left on the surface of the substrate 1001 during the etch back to form an isolation portion.

In the following, for convenience, the situation shown in FIG. 14(a) is still used as the example for description.

Next, the spacers 1017 may be used to complete the definition of the active region.

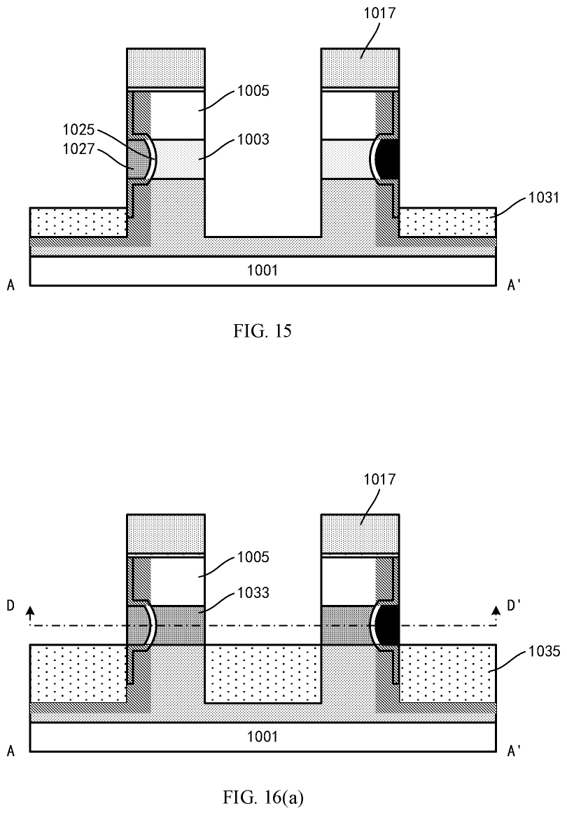

As shown in FIG. 15, the hard mask layer 1013 may be removed to expose the mandrel pattern 1011 by selective etching such as ME or planarization process such as CMP. During the removal of the hard mask layer 1013, a height of the spacer 1017, which is also a nitride in the example, may be decreased. Then, the mandrel pattern 1011 may be removed by selective etching such as wet etching using a TMAH solution or dry etching using ME. In this way, a pair of spacers 1017 extending opposite to each other are left on the ridge-like structure (a top topography may also be changed with the decrease of the height).

The etch stop layer 1009, the third material layer 1005, the second material layer 1003 and the upper part of the substrate 1001 may be selectively etched sequentially by, for example, RIE by using the spacers 1017 as an etching mask. The well region of the substrate 1001 may be etched. In this way, in a space surrounded by the isolation layer 1031, the third material layer 1005, the second material layer 1003 and the upper part of the substrate 1001 form a pair of stacks corresponding to the spacers 1017 to define the active region.

Certainly, the formation of the stack for defining the active region is not limited to the spacer transfer technique, and may also be performed by photolithography by using a photoresist or the like.

Here, for the purpose of epitaxial growth, the second material layer 1003 for defining the position of the gate stack includes a semiconductor material. In order to facilitate a subsequent replacement gate process, the second material layer 1003 may be replaced with a dielectric material to form a third position retaining layer.

For example, as shown in FIGS. 16(a) and 16(b), the second material layer 1003 (SiGe in the example) is removed by selective etching with respect to the first channel layer 1025, the substrate 1001 and the third material layer 1005 (all Si in the example). Then, a third position retaining layer 1033 may be formed in a gap left under the spacers 1017 due to the removal of the second material layer 1003. Likewise, the third position retaining layer 1033 may be formed by deposition and then etch-back. In the example, the third position retaining layer 1033 may contain the same material as the first position retaining layer 1019 and the second position retaining layer 1027 so that the third position retaining layer may be removed with the same etch recipe in the subsequent replacement gate process.

As shown in FIG. 16(b), the first position retaining layer 1019, the second position retaining layer 1027 and the third position retaining layer 1033 (which together define the position of the gate stack) surround a part of the first channel layer 1025. The part of the first channel layer 1025 may be used as the channel portion. It may be seen that the channel portion is a C-shaped curved nanosheet (when the nanosheet is narrow, for example, when a dimension in the vertical direction in the paper surface in FIG. 16(b) is small, it may become a nanowire). Due to a high etch selectivity with respect to the first channel layer 1025 (Si) when etching the second material layer 1003 (SiGe), the thickness of the channel portion (thickness or diameter in case of nanowire) is substantially determined by the selective growth process of the first channel layer 1025. This has a large advantage over a technique in which only etching or photolithography is used to determine the thickness, since the epitaxial growth process has much better process control than etching or photolithography.

In order to reduce the overlap between the gate stack and the source/drain portion, especially the underlying source/drain portion, a height of the isolation layer 1031 may be increased. For example, an isolation layer 1035 may be formed by deposition (and planarization) and then etch back. For example, the isolation layer 1035 may contain an oxide, and thus is shown as an integral with the previously-formed isolation layer 1031. A top surface of the isolation layer 1035 may be close to, for example, not be lower than (preferably, slightly higher than) a top surface of the first material layer (i.e., the top surface of the substrate 1001) or a bottom surface of the second material layer (i.e., a bottom surface of the first position retaining layer 1019, the second position retaining layer 1027 and the third position retaining layer 1033), and not higher than a top surface of the second material layer (i.e., a top surface of the first position retaining layer 1019, the second position retaining layer 1027, and the third position retaining layer 1033) or a bottom surface of the third material layer.

According to another embodiment of the present disclosure, in order to reduce the capacitance, the overlap between the gate portion and the first and third material layers (in which the source/drain portions are formed) may be further reduced. For example, as shown in FIG. 17, after the third position retaining layer 1033 is formed as described above, the exposed surfaces of the first material layer and the third material layer may be further concaved by selective etching. Thus, an overlap between the third position retaining layer 1033 (which subsequently defines the position of the gate stack) and the first and third material layers is reduced. After that, an isolation layer 1035′ may be formed similarly. In a process of forming the isolation layer 1035′, a dielectric material of the isolation layer 1035′ also fills gaps formed by a concave of the third material layer under the spacers 1017.

In the example of FIG. 17, a structure obtained by performing the process of reducing overlap described with reference to FIG. 17 in addition to the process of reducing overlap described with reference to FIG. 14(b) is shown. Thus, an outer periphery of the source/drain portion S/D is surrounded by the dielectric material. However, the present disclosure is not limited thereto. For example, the process of reducing overlap described with reference to FIG. 14(b) and the process of reducing overlap described with reference to FIG. 17 may be performed alternatively, or both of them may be performed.

In the following descriptions, the situation shown in FIGS. 16(a) and 16(b) is still taken as the example for description.

Next, a replacement gate process may be performed to form the gate stack.

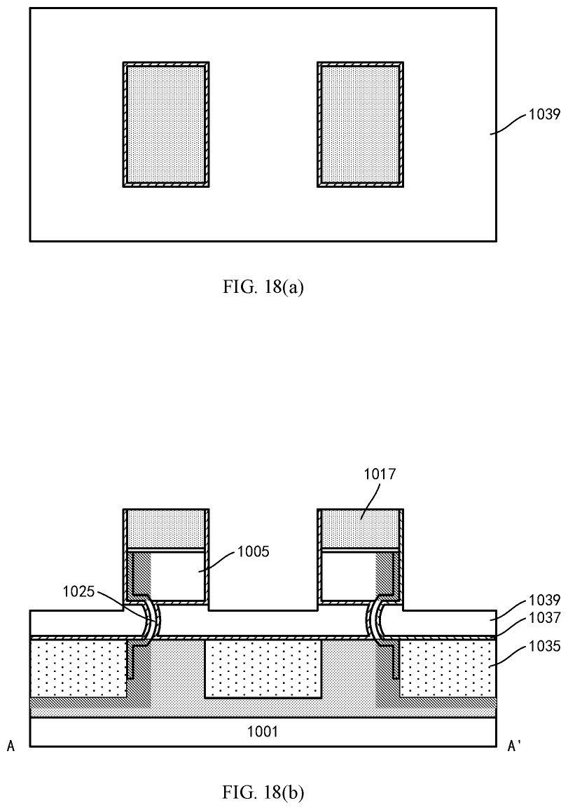

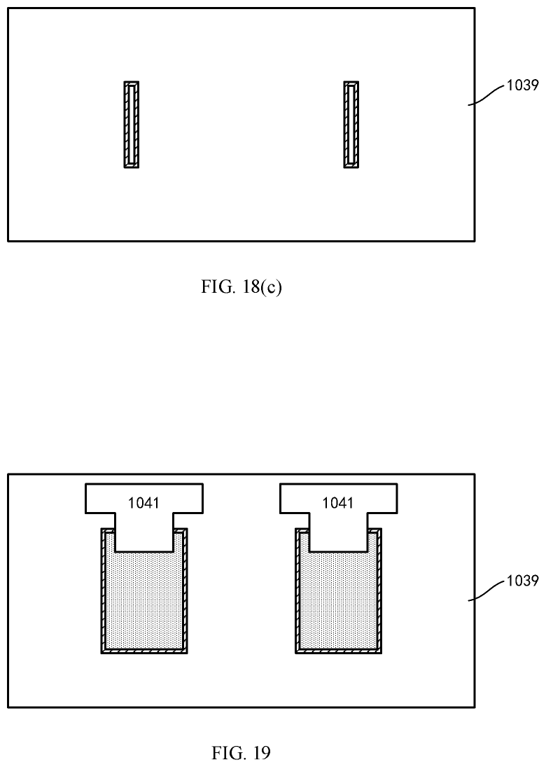

As shown in FIGS. 18(a) to 18(c), the first position retaining layer 1019, the second position retaining layer 1027 and the third position retaining layer 1033 may be removed by selective etching and a gate stack is formed on the isolation layer 1035. For example, a gate dielectric layer 1037 may be formed in a substantially conformal manner by deposition, and a gate conductor layer 1039 may be formed on the gate dielectric layer 1037. The gate conductor layer 1039 may be used to fill a space between the active regions. The gate conductor layer 1039 may be planarized, for example, by CMP, which may be stopped at the spacers 1017. Then, the gate conductor layer 1039 may be etched back so that its top surface is lower than the top surface of the original first position retaining layer 1019, the original second position retaining layer 1027 and the original third position retaining layer 1033 (or the top surface of the second material layer surface or the bottom surface of the third material layer) to reduce the capacitance between the source/drain portion and the gate stack. In this way, end portions of the formed gate stack are embedded in the space where the first position retaining layer 1019, the second position retaining layer 1027 and the third position retaining layer 1033 were previously located, so as to surround the channel portion.

For example, the gate dielectric layer 1037 may contain a high-k gate dielectric such as HfO₂ with a thickness of, for example, about 1 nm-5 nm. Before forming the high-k gate dielectric, an interface layer may also be formed which is, e.g., an oxide formed by an oxidation process or deposition such as atomic layer deposition (ALD), with a thickness of about 0.3 nm-1.5 nm. The gate conductor layer 1039 may contain a work function adjustment metal such as TiN, TaN, TiA1C, and a gate conductive metal such as W and the like.

Currently, the gate stacks of the two devices are integrally connected to each other. Depending on a device design, the gate conductor layer 1039 may be disconnected between the two devices by, for example, photolithography, while landing pads of gate contacts may also be patterned.

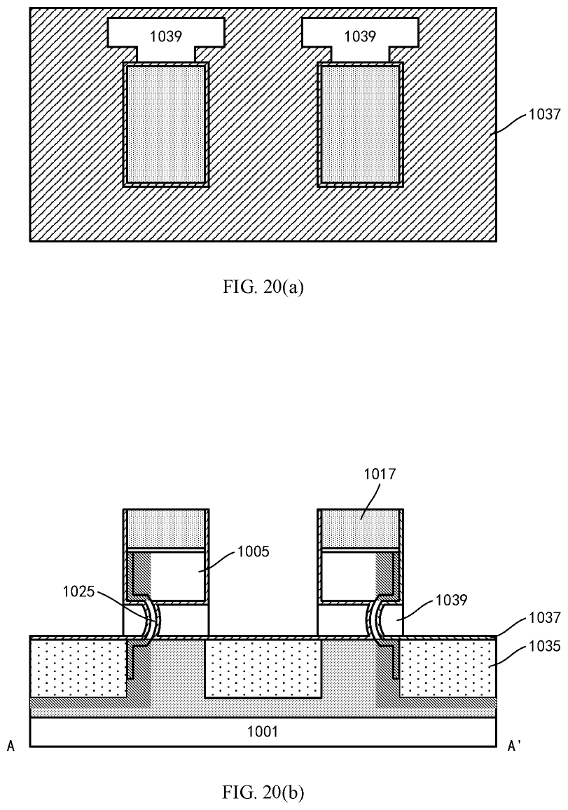

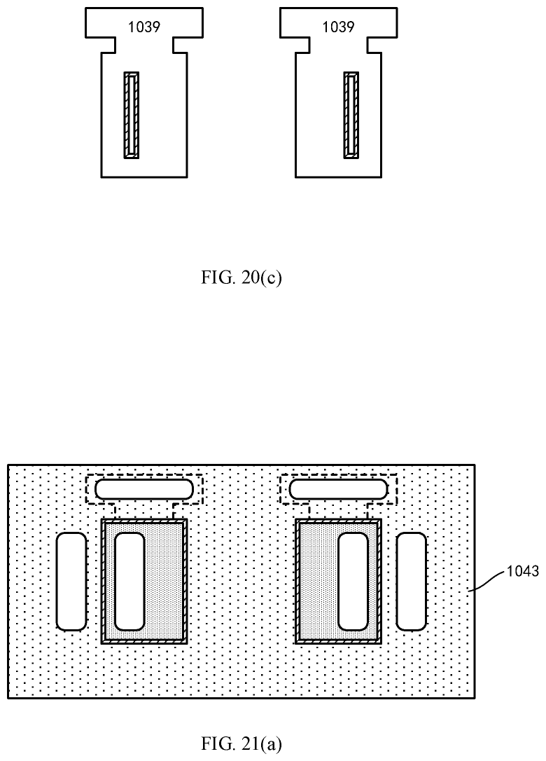

As shown in FIG. 19, a photoresist 1041 may be formed and patterned to shield areas to form the landing pads of the gate contacts while exposing other areas. Then, as shown in FIGS. 20(a) to 20(c), the photoresist 1041 (together with the spacers 1017) may be used as a mask to selectively etch the gate conductor layer 1039 by, for example, RIE, and the RIE may be stopped at the gate dielectric layer 1037. After that, the photoresist 1041 may be removed.

Thus, the gate conductor layer 1039 is substantially left and self-aligned under the spacers 1017, except that a part of the gate conductor layer is protruded on a side of the spacers 1017 (upper side in FIG. 20(a)) to be used as the landing pad. The gate conductor layer 1039 is separated between the two opposite devices respectively located under the opposite spacers 1017, and thus, the gate conductor layer is in combination with the gate dielectric layer 1037 to define gate stacks which are respectively used for the two devices.

In the example, the landing pads of each of the two devices are located on the same side of the spacers 1017. However, the present disclosure is not limited thereto. For example, the landing pads of each of the two devices may be located on different sides of the spacers 1017.

So far, the manufacture of a basic structure of the device is completed. After that, various contact portions, interconnection structures, and the like may be manufactured.

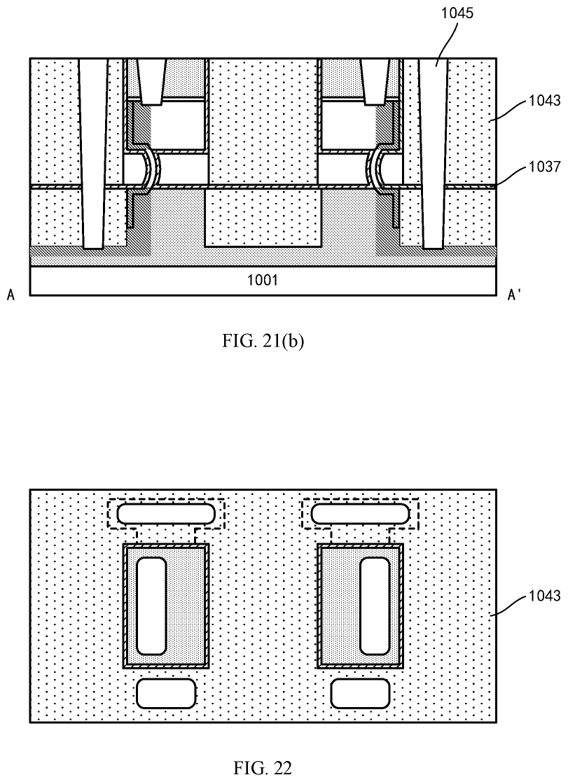

For example, as shown in FIGS. 21(a) and 21(b), a dielectric layer 1043 may be formed on the substrate by, for example, deposition and then planarization. Then, contact holes may be formed and filled with a conductive material such as metal to form contact portions 1045.

The contact portions 1045 may include contact portions connected to the upper source/drain portions through the spacers 1017 and the etch stop layer 1009, contact portions connected to contact regions of the lower source/drain portions through the dielectric layer 1043 and the isolation layer 1035, and contact portions connected to the landing pads of the gate conductor layer through the dielectric layer 1043. As shown in FIGS. 21(a) and 21(b), the contact portions connected to the contact regions of the lower source/drain portions of each of the two devices may be respectively located on two opposite sides of the active region (left and right sides in the drawing).

According to other embodiments of the present disclosure, the contact portions connected to the contact region of the lower end source/drain portion, and the contact portions connected to the landing pad of the gate conductor layer of the corresponding device may be located on two opposite sides of the active region of the corresponding device, as shown in FIG. 22.

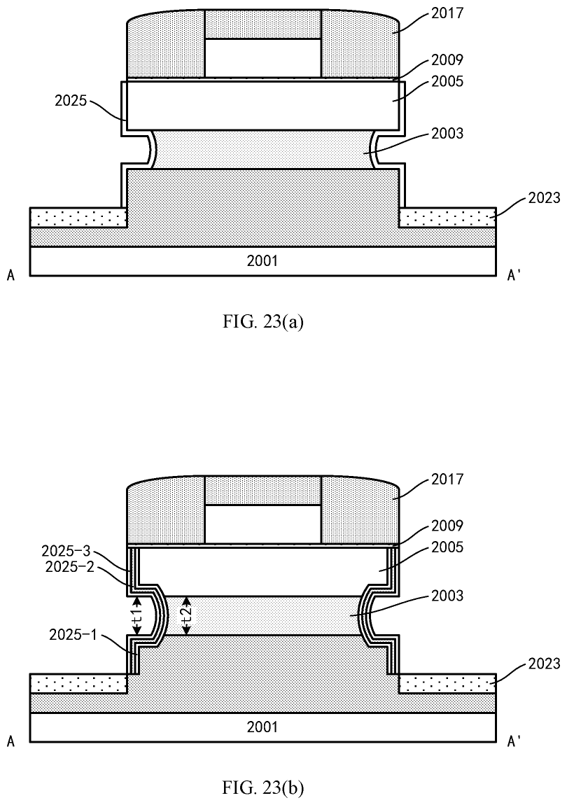

FIGS. 23(a) to 36 schematically show some stages in a process of manufacturing a semiconductor device according to another embodiment of the present disclosure. In the following, differences from the above-described embodiments will be mainly described.

The processes as described above with reference to FIGS. 1 to 8 may be performed to form a second material layer 2003, a third material layer 2005, an etch stop layer 2009 for facilitating patterning, spacers 2017, and the like, on the substrate. Concaves may be formed in the second material layer 2003, and a protective layer 2023 may be formed on the substrate 2001. For other undescribed components and processes, reference may be made to the above descriptions in conjunction with FIGS. 1 to 8.

The channel layer may be formed similarly. In the embodiment, a plurality of channel layers stacked in sequence may be formed.

For example, as shown in FIG. 23(a), a preliminary channel layer 2025 may be formed on a sidewall of the ridge-like structure by, for example, selective epitaxial growth. Due to the selective epitaxial growth, the preliminary channel layer 2025 may be formed only on a semiconductor surface. A thickness of the preliminary channel layer 2025 may be approximately equal to a sum (L1+L2) of thicknesses of a first channel layer (e.g., a first thickness L1) and a second channel layer (e.g., a second thickness L2) that will be subsequently formed. For example, the thickness of the preliminary channel layer is about 3 nm-15 nm. The thickness of the preliminary channel layer 2025 is selected such that gate lengths on the left and right sides of the subsequent C-shaped channel portion may be substantially equal to each other, which will be further described below.

A material of the preliminary channel layer 2025 may be appropriately selected according to performance requirements of the device. For example, the preliminary channel layer 2025 may contain various semiconductor materials such as Si, Ge, SiGe, InP, GaAs, InGaAs, and the like. In the example, the preliminary channel layer 2025 may contain the same material, such as Si, as the first material layer and the third material layer.

According to another embodiment, as shown in FIG. 23(b), a first channel layer 2025-1, a second channel layer 2025-2 and a third channel layer 2025-3 may be sequentially formed on the sidewall of the ridge-like structure by, for example, selective epitaxial growth. A thickness of the first channel layer 2025-1 may be a first thickness L1 of, for example, about 3 nm-5 nm; a thickness of the second channel layer 2025-2 may be a second thickness L2 of, for example, about 1 nm-3 nm; and a thickness of the third channel layer 2025-3 may be approximately the same as the thickness of the first channel layer 2025-1 (which is the first thickness L1) of, for example, about 3 nm-5 nm.

According to the embodiment of the present disclosure, in order to keep the gate lengths (for example, in the direction perpendicular to the substrate surface) of the gate stacks on the left and right sides of the C-shaped channel portion to be substantially equal, before forming the channel layer, the ridge-like structure (specifically, exposed surfaces of the first material layer, the second material layer, and the third material layer) may be etched back so that peripheral sidewalls thereof are laterally concaved relative to peripheral sidewalls of the spacers 2017. To control an amount of etching, ALE may be used. For example, the amount of etching may be approximately a sum of the thicknesses of the first channel layer 2025-1, the second channel layer 2025-2 and the third channel layer 2025-3 to be formed, that is, (2L1+L2), for example, which is about 4 nm-20 nm. Thus, the first channel layer 2025-1, the second channel layer 2025-2 and the third channel layer 2025-3 may be (at least partially) shielded from above by the spacers 2017.

In FIG. 23(b), sidewalls of parts of the outermost third channel layer 2025-3 on the sidewalls of the first material layer and the third material layer are shown to be substantially aligned with the sidewalls of the spacers 2017. This may be achieved by controlling the amount of etch back and a total epitaxial growth thickness to be substantially the same. However, the present disclosure is not limited thereto. For example, the sidewalls of parts of the outermost third channel layer 2025-3 on the sidewalls of the first material layer and the third material layer may be concaved or even protruded relative to the sidewalls of the spacers 2017.

Here, the above etch back may be performed to etch upper and lower ends of the concave portion upwardly and downwardly, respectively, so that after the first channel layer 2025-1, the second channel layer 2025-2 and the third channel layer 2025-3 are grown, a height t1 of the concave portion may be substantially the same as a thickness t2 of the second material layer 2003. In this way, the gate stacks that will be subsequently formed on the left and right sides of the channel portion formed by the first channel layer 2025-1, the second channel layer 2025-2 and the third channel layer 2025-3 may have substantially equal gate lengths. However, the present disclosure is not limited thereto. According to the embodiment of the present disclosure, the gate length outside the channel portion may also be changed by adjusting the amount of etch back, thereby changing a ratio of the gate lengths on the two sides, so as to optimize an influence on the device performance due to the different topographies on the left and right sides of the C-shaped channel portion.

The ridge-like structure may also be etched back although the etch back is not shown in the example shown in FIG. 23(a).

According to the embodiment of the present disclosure, the thickness of each channel layer (which is subsequently used as the channel portion) may be determined through an epitaxial growth process, and thus the thickness of the channel portion may be better controlled. The thickness of each channel layer formed by epitaxial growth may be substantially uniform.

Each channel layer may be doped in-situ during the epitaxial growth to adjust a threshold voltage of the device.

Likewise, materials of the first channel layer 2025-1, the second channel layer 2025-2, and the third channel layer 2025-3 may be appropriately selected. For example, each of the first channel layer 2025-1, the second channel layer 2025-2, and the third channel layer 2025-3 may contain various semiconductor materials, such as Si, Ge, SiGe, InP, GaAs, InGaAs, and the like.

According to embodiment of the present disclosure, at least some of the first channel layer 2025-1, the second channel layer 2025-2, and the third channel layer 2025-3 may have different characteristics to optimize the device performance.

For example, the second channel layer 2025-2 may contain a material with a high carrier mobility (relative to the first channel layer 2025-1 and the third channel layer 2025-3) such as SiGe (e.g., an atomic percentage of Ge is about 30%-100%, and becoming Ge when the atomic percentage of Ge is 100%) to improve a device current capability. However, an interface quality between SiGe and a gate dielectric layer that will be subsequently formed may be poor (e.g., high charge density of interface states, high carrier scattering due to surface roughness, or high channel resistance, etc.). To this end, the first channel layer 2025-1 and the third channel layer 2025-3 may contain a material, such as Si, having a good interface quality with the gate dielectric layer.

As another example, the first channel layer 2025-1 and the third channel layer 2025-3 may contain a material with a high carrier mobility (relative to the second channel layer 2025-2), and the second channel layer 2025 -2 may contain a material capable of optimizing a carrier distribution.

For yet another example, the second channel layer 2025-2 may restrict carriers in the first channel layer 2025-1 and/or the third channel layer 2025-3, so as to be closer to the gate dielectric layer, which is conducive to improving a short channel effect and reducing a leakage current. For example, for an n-type device, a lowest energy level of a conduction band of the second channel layer 2025-2 may be higher than a lowest energy level of a conduction band of the first channel layer 2025-1 and/or the third channel layer 2025-3 level; for a p-type device, a highest energy level of a valence band of the second channel layer 2025-2 may be lower than a highest energy level of a valence band of the first channel layer 2025-1 and/or the third channel layer 2025-3.

In the examples shown in FIGS. 23(a) and 23(b), the channel layers on the two opposite sides of the ridge-like structure in the second direction may have substantially the same characteristics (e.g., material, dimension, doping characteristics, etc.), and may be symmetrically arranged with each other on the two opposite sides of the second material layer. However, the present disclosure is not limited thereto. As described above, depending on the design, the channel layers on the opposite sides of the ridge-like structure may have different characteristics in, for example, at least one aspect of thickness, material and doping characteristics.

In the following, for convenience, FIG. 23(a) is mainly taken as the example for description.

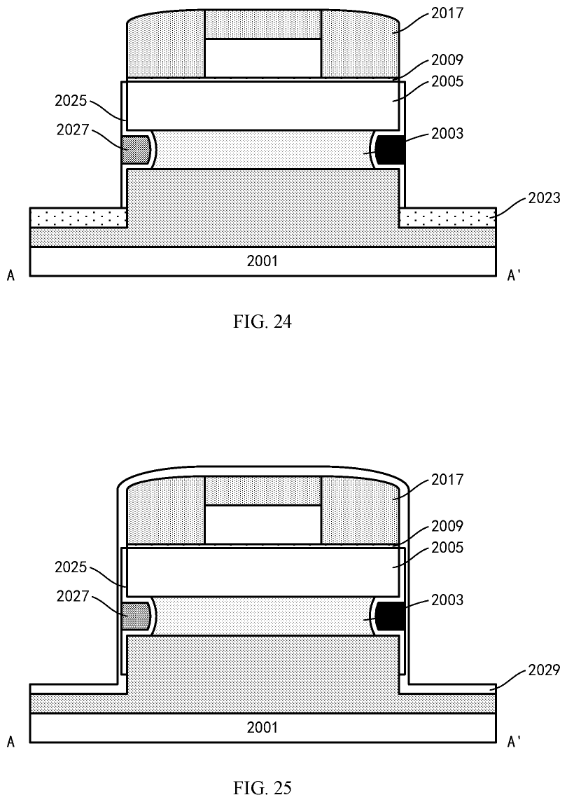

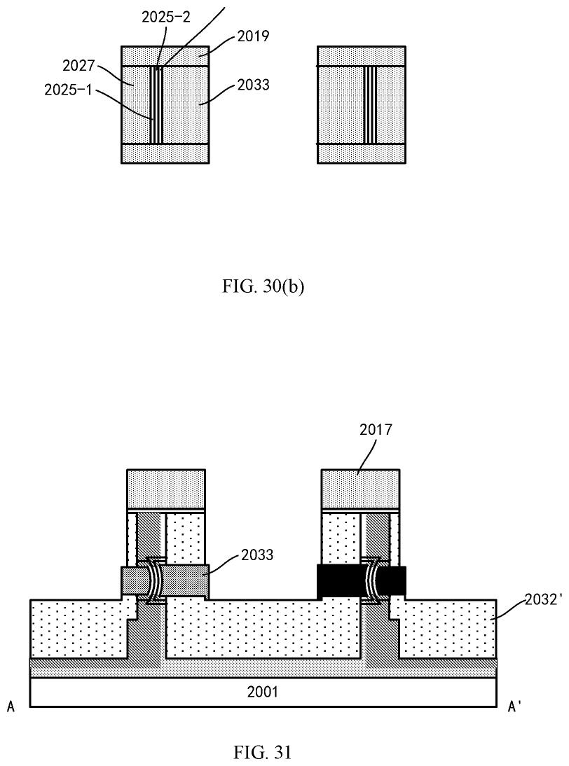

Similarly, as shown in FIG. 24, a second position retaining layer 2027 may be formed. The second position retaining layer 2027 may contain the same material such as SiC as the previously formed first position retaining layer (refer to 2019 in FIG. 30(b), for details thereof, reference may be made to the descriptions of the first position retaining layer 1019 in the above embodiment), so that they may be subsequently removed together by one same etch recipe. However, the present disclosure is not limited to this. For example they may contain different materials.

After that, source/drain doping may be performed.

As shown in FIG. 25, a solid phase dopant source layer 2029 may be formed on the structure shown in FIG. 24 by, for example, deposition. The solid phase dopant source layer 2029 may be formed in a substantially conformal manner. Regarding the solid phase dopant source layer 2029, reference may be made to the above descriptions regarding the solid phase dopant source layer 1029.

In the example, before forming the solid phase dopant source layer 2029, a protective layer that is present on the surface of the substrate 2001 may be selectively etched by, for example, RIE (e.g., see 2023 in FIGS. 23(a) and 23(b)) to expose the surface of the substrate 2001. In this way, the exposed surface of the substrate 2001 may also be doped to form contact regions of each of the source/drain portions S/D at lower ends of the two devices.

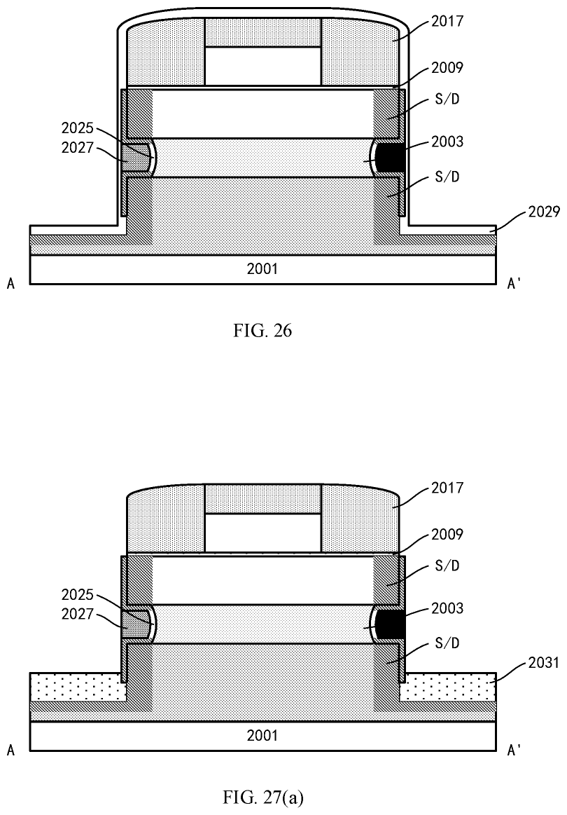

As shown in FIG. 26, the dopant in the solid phase dopant source layer 2029 may be driven into the preliminary channel layer 2025, the first material layer and the third material layer by annealing to form the source/drain portions S/D (and optionally, the dopant may be driven into the exposed surface of the substrate 2001 to form the contact regions of each of the source/drain portions S/D at the lower ends of the two devices). After that, the solid phase dopant source layer 2029 may be removed.

Since the first material layer and the third material layer may contain the same material, and the solid phase dopant source layer 2029 may be formed on their surfaces in the substantially conformal manner, degrees of the dopant driven from the solid phase dopant source layer 2029 into the first material layer and the third material layer may be approximately the same. Therefore, (doping concentration) interfaces of the source/drain portions S/D (with inner parts of the first material layer and the third material layer) may be approximately parallel to the surfaces of the first material layer and the third material layer, that is, they may be aligned with each other in a vertical direction.

In the example, the first material layer is provided by the upper part of the substrate 2001. However, the present disclosure is not limited thereto. For example, the first material layer may also be an epitaxial layer on the substrate 2001. In this case, the first material layer and the third material layer may be doped in-situ during epitaxial growth, rather than doped by using the solid phase dopant source layer.

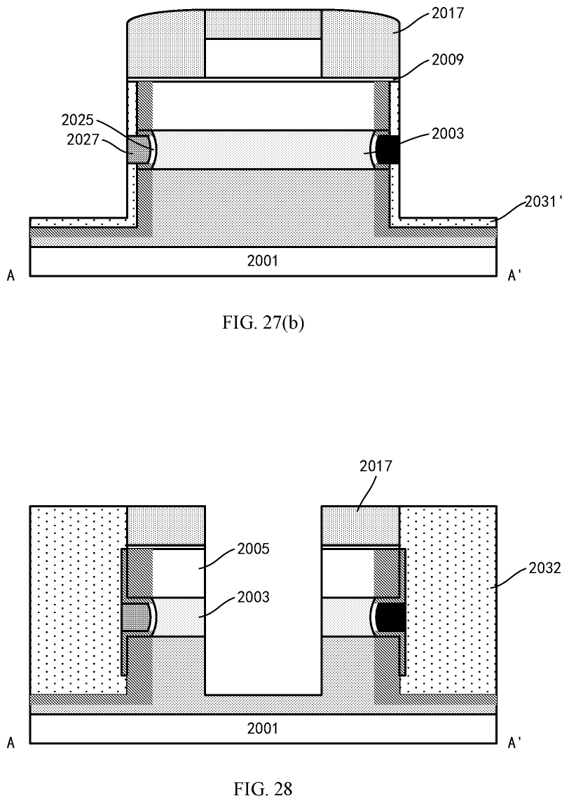

As shown in FIG. 27(a), in the recesses surrounding the ridge-like structures, an isolation layer 2031 may be formed.

To reduce a capacitance between the gate and the source/drain portions, an overlap between the gate and the source/drain portions may be further reduced. For example, as shown in FIG. 27(b), after the solid-phase dopant source layer 2029 is removed, the source/drain portions S/D may be further concaved by selective etching, so that the overlap between the source/drain portions S/D and each of the first position retaining layer and the second position retaining layer 2027 (which subsequently define the position of the gate stack) is reduced. In the example, when the source/drain portions S/D is further concaved, the parts of the preliminary channel layer 2025 on the sidewalls of the first material layer and the third material layer are removed, and the first material layer and the third material layer may be further concaved. In gaps formed under the hard mask layer and the spacer 2017 due to the concave of the source/drain portion S/D, a dielectric 2031′ such as an oxynitride or an oxide may be filled. The filling may be achieved by deposition (and planarization) and then etch back. A certain thickness of the dielectric 2031′ is left on the surface of the substrate 2001 during the etch back to form an isolation portion.

In the following, for convenience, the situation shown in FIG. 27(a) is still used as the example for description.

Next, the spacer 2017 may be used to complete the definition of the active region.

In the example, since a part of the preliminary channel layer 2025 is protruded outside the spacer 2017, in order to prevent subsequent processing from adversely affecting the preliminary isolation layer 2025, a protective layer may be formed on the isolation layer 2031 first to cover the preliminary isolation layer 2025. As shown in FIG. 28, a dielectric material such as an oxide may be further formed on the isolation layer 2031 by, for example, deposition. The deposited dielectric material may be planarized such as CMP (which may be stopped at the hard mask layer). In the example, the formed dielectric material is shown as 2032 along with the previous isolation layer 2031 (both are oxides in the example).

After that, the hard mask layer and the mandrel pattern may be removed as described above in conjunction with FIG. 15, so that a pair of spacers 2017 extending opposite to each other are left on the ridge-like structure (a top topography may also be changed with a decrease in height). By selective etching such as RIE in which the spacers 2017 are used as an etch mask (the etching may proceed into the well region of the substrate 2001), in a space surrounded by the isolation layer (protective layer) 2032, the third material layer 2005, the second material layer 2003 and the upper part of the substrate 2001 are patterned as a pair of stacks corresponding to the spacers 2017 to define the active regions. Due to a presence of the isolation layer (protective layer) 2032, the preliminary channel layer 2025 (in this example, containing Si as the third material layer 2005 and the substrate 2001) may be protected from an influence of etching.

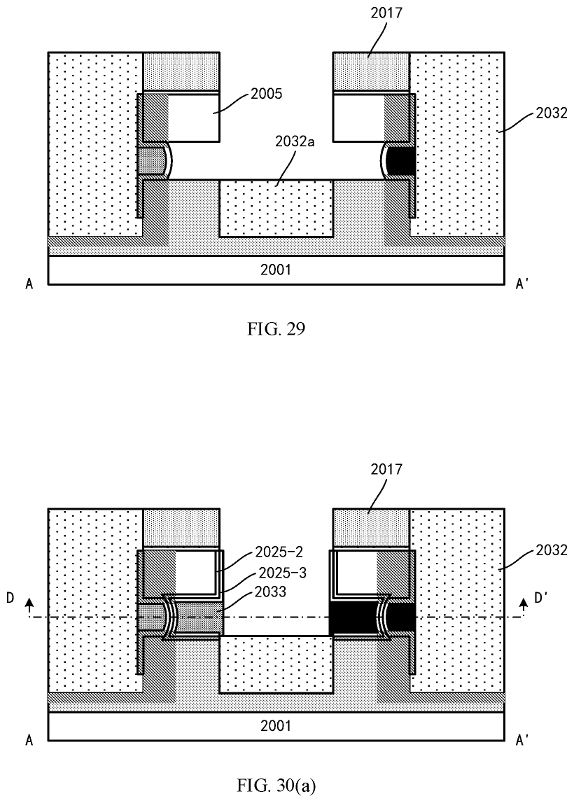

As shown in FIG. 29, between the pair of stacks for defining the corresponding active regions, an isolation layer 2032a (e.g., an oxide) may be formed in the manner of forming the isolation layer as described above. The isolation layer 2032a may be etched back so that its top surface is lower than a top surface of the second material layer 2003, thereby exposing (at least a part of) sidewalls of the second material layer 2003 for a subsequent removal. In the example, a top surface of the etched back isolation layer 2032a is close to (e.g., slightly lower than) a bottom surface of the second material layer 2003 to fully expose the sidewalls of the second material layer 2003. Of course, the formation of the isolation layer 2032a between the stacks may also be integrated into subsequent process of forming the isolation layer 2035.

In the example, in order to form a stack structure of a plurality of nanosheets/nanowires, an additional channel layer may continue to be grown based on the preliminary channel layer 2025. To this end, the second material layer 2003 may be removed to expose the preliminary channel layer 2025.

For example, as shown in FIG. 29, the second material layer 2003 (SiGe in the example) may be removed relative to the preliminary channel layer 2025, the substrate 2001 and the third material layer 2005 (all Si in the example) through selective etching.

Due to a high etch selectivity relative to Si when SiGe is etched, the thickness of the preliminary channel layer 2025 in the form of nanosheet is mainly determined by the epitaxial growth process. As described above, the preliminary channel layer 2025 is formed by (isotropically) selectively etching the second material layer 2003 and through epitaxial grown, and the preliminary channel layer may have a C shape. Compared to a method is which only etching or photolithography is used, the method of the present disclosure has an advantage in thickness control of the preliminary channel layer 2025 since the epitaxial growth process has better process control than etching or photolithography.

In order to keep gate lengths of gate stacks substantially equal when the gate stacks are subsequently formed on the left and right sides of the C-shaped channel portion, as shown in FIGS. 30(a) and 30(b), exposed surfaces of the preliminary channel layer 2025, the first material layer and the third material layer (Si in the example) are etched back. The etched back preliminary channel layer 2025 forms the first channel layer 2025-1. ALE may be used to better control the amount of etching. For example, the amount of etch back may be approximately the second thickness L2. Thus, the thickness of the first channel layer 2025-1 may be approximately the first thickness L1. After that, the second channel layer 2025-2 and the third channel layer 2025-3 may be sequentially formed by, for example, selective epitaxial growth. The thickness of the second channel layer 2025-2 may be approximately the second thickness L2, and the thickness of the third channel layer 2025-3 may be approximately the same as the thickness of the first channel layer 2025-1, approximately the first thickness L1. Regarding the materials of the first channel layer 2025-1, the second channel layer 2025-2 and the third channel layer 2025-3, reference may be made to the above descriptions in conjunction with FIG. 23(b).

Here, the amount of the selective etching may be the second thickness L2, so that the substantially the same gate length may be formed on two sides of the subsequently formed C-shaped channel portion. In fact, the gate lengths on the two sides of the C-shaped channel portion may be adjusted by adjusting the amount of etch back (or etching back the ridge-like structure before the epitaxial growth process described in conjunction with FIG. 23(a), and controlling the amount of etch back).

Similarly, as described above, the use of epitaxial growth process has advantages over methods of etching or photolithographic in determining thickness.

As described above, the first material layer and the third material layer are also etched during the etch back process, which may cause a discontinuity between the source/drain portions S/D and the channel portion. To this end, an annealing treatment may be performed to drive the dopant into a newly grown active layer to form the source/drain portions S/D and an a doping profile in an extension region.

It should be pointed out here that, if the structure shown in FIG. 23(b) is adopted, the processes of etching and then epitaxial growth may be omitted, and only the second material layer 2003 needs to be removed.

After that, a third position retaining layer 2033 may be formed in a gap that is left under the spacer 2017 due to the removal of the second material layer 2003. The third position retaining layer 2033 may contain the same material, such as SiC, as the first position retaining layer 2019 and the second position retaining layer 2027, so that the third position retaining layer may be removed together with the same etch recipe in the subsequent replacement gate process.

As shown in FIG. 30(b), the first position retaining layer 2019, the second position retaining layer 2027 and the third position retaining layer 2033 (which together define the position of the gate stack) surround a part of the first channel layer 2025-1, a part of the second channel layer 2025-2 and a part of the third channel layer 2025-3. The part of the first channel layer 2025-1, the part of the second channel layer 2025-2, and the part of the third channel layer 2025-3 may be used as the channel portion. It may be seen that the channel portion is a C-shaped curved nanosheet (when the nanosheet is narrow, for example, when a dimension in the vertical direction in the paper surface in FIG. 30(b) is small, it may become a nanowire). As described above, the thickness of the channel portion (thickness or diameter in the case of nanowires) is mainly determined by the selective growth process of each channel layer. This has a huge advantage over a technique in which only etching or photolithography is used to determine the thickness, since the epitaxial growth process has much better process control than etching or photolithography.

According to another embodiment of the present disclosure, in order to reduce the capacitance, the overlap between the gate and the first and third material layers (in which the source/drain portions are formed) may be further reduced. For example, as shown in FIG. 31, after the third position retaining layer 2033 is formed as described above, the exposed surfaces of the first material layer and the third material layer may be further concaved by selective etching. Thus, an overlap between the third position retaining layer 2033 (which subsequently defines the position of the gate stack) and the first and third material layers is reduced. After that, an isolation layer 2032′ may be formed similarly.

In the example of FIG. 31, a structure obtained by performing the process of reducing overlap described with reference to FIG. 31 in addition to the process of reducing overlap described with reference to FIG. 27(b) is shown. Thus, an outer periphery of the source/drain portions S/D is surrounded by the dielectric material. However, the present disclosure is not limited thereto. For example, the process of reducing overlap described with reference to FIG. 27(b) and the process of reducing overlap described with reference to FIG. 31 may be performed alternatively, or both of them may be performed.

In the following descriptions, the situation shown in FIGS. 30(a) and 30(b) is still taken as the example for description.

Next, a replacement gate process may be performed to form the gate stack.

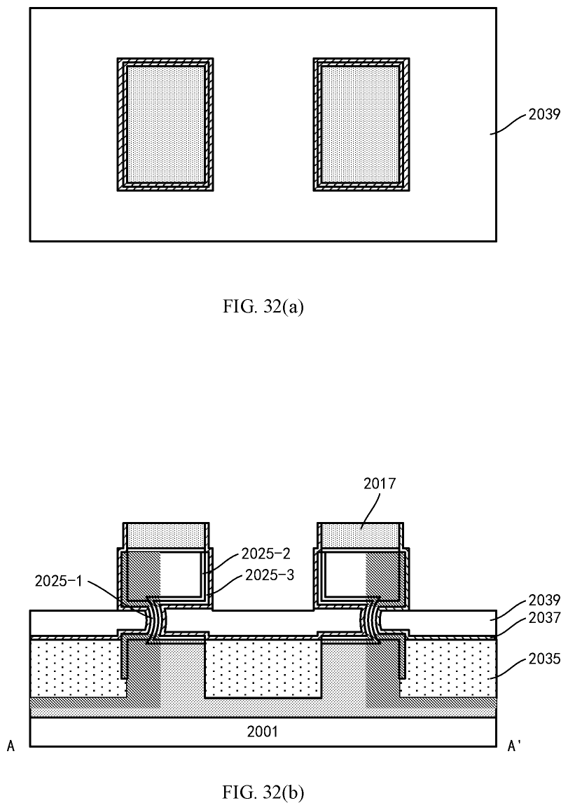

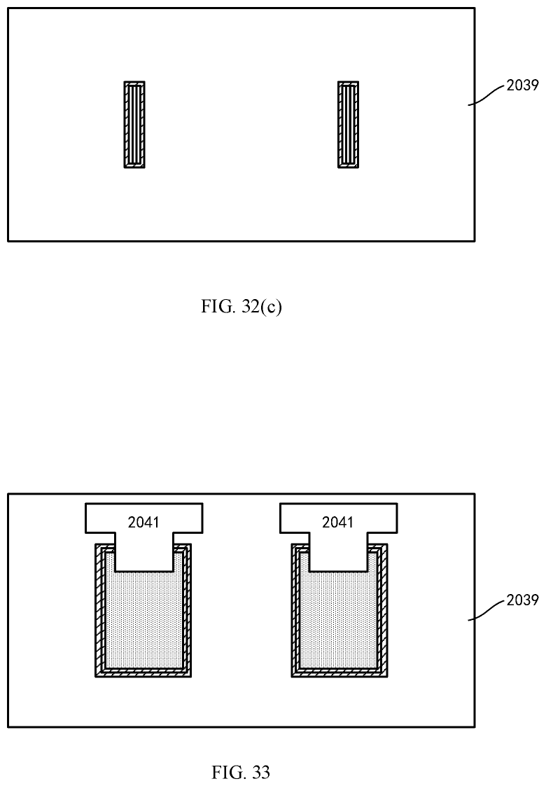

Since the isolation layer 2032 currently covers the first position retaining layer 2019 and the second position retaining layer 2027, a height of the isolation layer 2032 may be reduced to (at least partially) expose the first position retaining layer 2019 and the second position retaining layer 2027, so that they will be easily removed. For example, as shown in FIGS. 32(a) to 32(c), a dielectric such as an oxide may be deposited on the structure shown in FIGS. 30(a) and 30(b), and the deposited dielectric may be planarized such as CMP (which may be stopped at the spacer 2017), and the planarized dielectric is etched back such as RIE to obtain an isolation layer 2035. A top surface of the isolation layer 2035 may be close to, for example, not lower than (preferably, slightly higher than) a top surface of the first material layer (i.e., the top surface of the substrate 2001) or a bottom surface of the second material layer (i.e., a bottom surface of the first position retaining layer 2019, the second position retaining layer 2027, and the third position retaining layer 2033), and not higher than a top surface of the second material layer (i.e., a top surface of the first position retaining layer 2019, the second position retaining layer 2027, and the third position retaining layer 2033) or a bottom surface of the third material layer.

The first position retaining layer 2019, the second position retaining layer 2027 and the third position retaining layer 2033 may be removed by selective etching, and a gate stack may be formed on the isolation layer 2035. For example, a gate dielectric layer 2037 may be formed in a substantially conformal manner by deposition, and the gate conductor layer 2039 may be formed on the gate dielectric layer 2037. The gate conductor layer 2039 may fill a space between the active regions. The gate conductor layer 2039 may be planarized such as CMP, which may be stopped at the spacers 2017. Then, the gate conductor layer 2039 may be etched back so that its top surface is lower than the top surface of the first position retaining layer 2019, the second position retaining layer 2027 and the third position retaining layer 2033 (or the top surface of the second material layer surface or the bottom surface of the third material layer) to reduce the capacitance between the source/drain portions and the gate stack. In this way, end portions of the formed gate stack are embedded in the space where the first position retaining layer 2019, the second position retaining layer 2027 and the third position retaining layer 2033 were previously located, so as to surround the channel portion.

For details of the gate dielectric layer 2037 and the gate conductor layer 2039, reference may be made to the above descriptions of the gate dielectric layer 1037 and the gate conductor layer 1039.

Similarly, a shape of the gate conductor layer 2039 may be adjusted according to the device design.

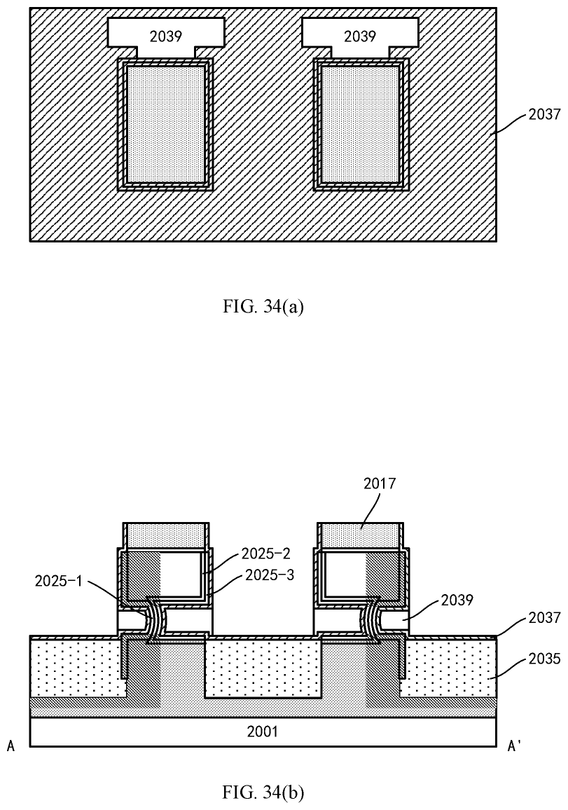

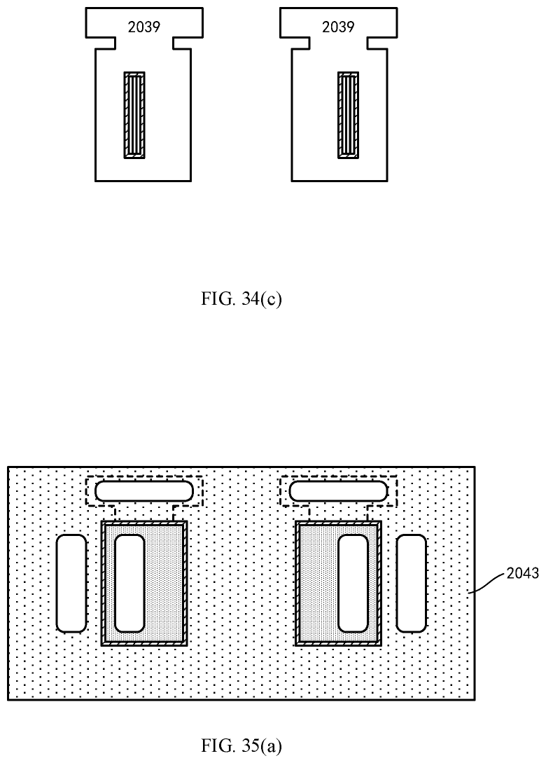

As shown in FIG. 33, a photoresist 2041 may be formed and patterned to shield an area to form landing pads of gate contacts while exposing other areas. Then, as shown in FIGS. 34(a) to 34(c), the photoresist 2041 (and the spacers 2017) may be used as a mask to selectively etch the gate conductor layer 2039 by, for example, RIE, and the RIE may be stopped at the gate dielectric layer 2037. Afterwards, the photoresist 2041 may be removed.

Thus, the gate conductor layer 2039 is substantially left and self-aligned under the spacers 2017, except that a part of the gate conductor layer is protruded on a side of the spacer s2017 (upper side in FIG. 34(a)) to be used as the landing pads. The gate conductor layer 2039 is separated between the two opposite devices respectively located under the opposite spacers 2017, and thus, the gate conductor layer is in combination with the gate dielectric layer 2037 to define gate stacks for the two devices, respectively.

In this example, the landing pads of each of the two devices are located on the same side of the spacers 2017. However, the present disclosure is not limited thereto. For example, the landing pads of each of the two devices may be located on different sides of the spacers 2017.

So far, the manufacture of a basic structure of the device is completed. After that, various contact portions, interconnection structures, and the like may be manufactured.

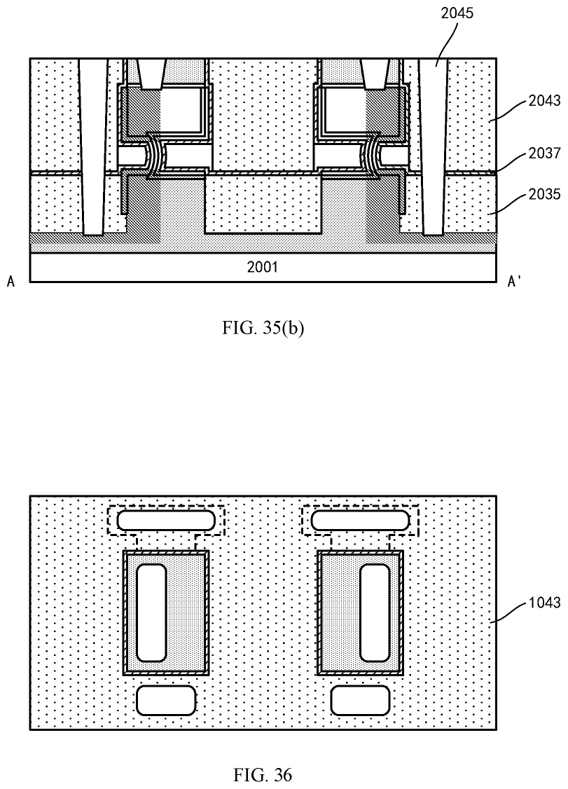

For example, as shown in FIGS. 35(a) and 35(b), a dielectric layer 2043 may be formed on the substrate by, for example, deposition and then planarization. Then, contact holes may be formed and filled with a conductive material such as metal to form contact portions 2045. The contact portions 2045 may include contact portions that are connected to upper source/drain portions through the spacers 2017 and the etch stop layer (see 1009 in the above embodiments), contact portions that are connected to contact regions of the lower source/drain portions through the dielectric layer 2043 and the isolation layer 2035, and contact portions that are connected to the landing pads of the gate conductor layer through the dielectric layer 2043. As shown in FIGS. 35(a) and 35(b), the contact portions that are connected to the contact regions of the lower source/drain portion of each of the two devices may be respectively located on two opposite sides of the active region (left and right sides in the drawing).

According to other embodiments of the present disclosure, the contact portions that are connected to the contact regions of the lower source/drain portion, and the contact portions that are connected to the landing pads of the gate conductor layer of the corresponding device may be located on two opposite sides of the active region of the corresponding device, as shown in FIG. 36.

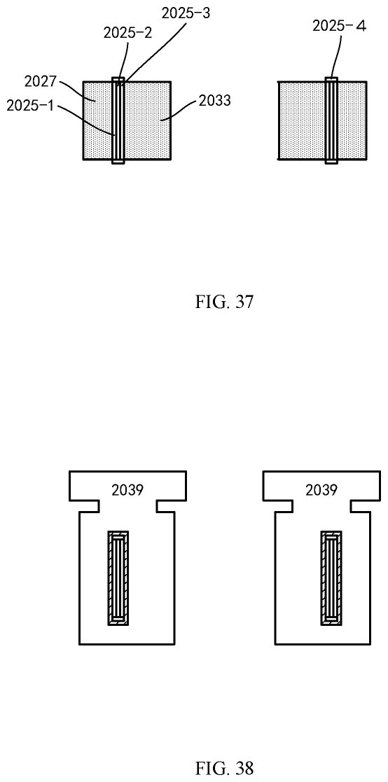

In the above embodiments, the first position retaining layer 2019 contains the same material, such as SiC, as the second position retaining layer 2027 and the third position retaining layer 2033, so as to be removed together in the replacement gate process. According to another embodiment of the present disclosure, the first position retaining layer 2019 may contain a different material, such as oxynitride, from the second position retaining layer 2027 and the third position retaining layer 2033. In this case, before performing the replacement gate process, the first position retaining layer 2019 may be removed first, thereby exposing end portions of the first channel layer 2025-1, the second channel layer 2025-2 and the third channel layer 2025-3 in the first direction. A fourth channel layer 2025-4 may be formed on the exposed end portions by, for example, selective epitaxial growth, as shown in FIG. 37. The fourth channel layer 2025-4 may be used to connect the end portions of the first channel layer 2025-1 and the third channel layer 2025-3 (and thus may also be referred to as a connection portion). Thus, the first channel layer 2025-1, the third channel layer 2025-3 and the fourth channel layer 2025-4 may be used to surround the second channel layer 2025-2. The fourth channel layer 2025-4 may contain the same material as the first channel layer 2025-1 and the third channel layer 2025-3. In addition, the fourth channel layer 2025-4 may have the same thickness of, for example, L1 as the first channel layer 2025-1 and the third channel layer 2025-3. However, since surface properties of nanoscale end portions may be different from those of other surfaces, the thickness of the fourth channel layer 2025-4 may be different from thicknesses of the first channel layer 2025-1 and the third channel layer 2025-3. The replacement gate process may be performed subsequently. FIG. 38 shows the gate stack and the channel portion in this case.

The semiconductor device according to the embodiments of the present disclosure may be applied to various electronic apparatuses. For example, an integrated circuit (ICs) may be formed based on such semiconductor device, and an electronic apparatus may be constructed therefrom. Accordingly, the present disclosure also provides an electronic apparatus including the above-described semiconductor device. The electronic apparatus may also include components such as a display screen cooperating with the integrated circuit, a wireless transceiver cooperating with the integrated circuit, etc. Such electronic apparatus is, for example, a smartphone, a computer, a tablet computer (PC), a wearable smart apparatus, a portable power supply, etc.

According to the embodiment of the present disclosure, a method of manufacturing a system on a chip (SoC) is also provided. The method may include the methods described above. Specifically, a plurality of of devices may be integrated on a chip, and at least some of which are manufactured according to the methods of the present disclosure.

In the above descriptions, technical details such as patterning and etching of each layer are not described in detail. However, those skilled in the art should understand that various technical means may be used to form layers, regions, etc. of desired shapes. In addition, in order to form the same structure, those skilled in the art may also design methods that are not completely the same as those described above. Additionally, although the various embodiments have been described above separately, this does not mean that the measures in the various embodiments may not be used in combination advantageously.

The embodiments of the present disclosure have been described above. However, the embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and the substitutions and modifications should all fall within the scope of the present disclosure.

1. A semiconductor device, comprising:
a channel portion on a substrate, wherein the channel portion comprises a curved nanosheet/nanowire with a C-shaped cross section;
source/drain portions respectively located at upper and lower ends of the channel portion with respect to the substrate; and
a gate stack surrounding a periphery of the channel portion.

2. The semiconductor device according to claim 1, wherein the channel portion comprises a plurality of the curved nanosheets/nanowires that are sequentially stacked in a lateral direction with respect to the substrate, and a cross section of each of the plurality of the curved nanosheets/nanowires has a C-shaped cross section.

3. The semiconductor device according to claim 2, wherein at least some of the plurality of the curved nanosheets/nanowires have different characteristics.

4. The semiconductor device according to claim 2, wherein the plurality of the curved nanosheets/nanowires comprise a first nanosheet/nanowire, a second nanosheet/nanowire and a third nanosheet/nanowire, the first nanosheet/nanowire and the second nanosheet/nanowire are located on two sides of the channel portion in the lateral direction, and the third nanosheet/nanowire is located between the first nanosheet/nanowire and the second nanosheet/nanowire;
wherein the first nanosheet/nanowire and the second nanosheet/nanowire have an improved interface quality with the gate stack; and
wherein the third nanosheet/nanowire has a high carrier mobility.

5. The semiconductor device according to claim 2, wherein the plurality of the curved nanosheets/nanowires comprise a first nanosheet/nanowire, a second nanosheet/nanowire and a third nanosheet/nanowire, the first nanosheet/nanowire and the second nanosheet/nanowire are located on two sides of the channel portion in the lateral direction, and the third nanosheet/nanowire is located between the first nanosheet/nanowire and the second nanosheet/nanowire;
wherein the first nanosheet/nanowire and the second nanosheet/nanowire have a high carrier mobility; and
wherein the third nanosheet/nanowire is capable of optimizing a carrier distribution.

6. The semiconductor device according to claim 2, wherein the plurality of the curved nanosheets/nanowires comprise a first nanosheet/nanowire, a second nanosheet/nanowire and a third nanosheet/nanowire, the first nanosheet/nanowire and the second nanosheet/nanowire are located on two sides of the channel portion in the lateral direction, and the third nanosheet/nanowire is located between the first nanosheet/nanowire and the second nanosheet/nanowire;
wherein the semiconductor device is an n-type device, and a lowest energy level of a conduction band of the third nanosheet/nanowire is higher than a lowest energy level of a conduction band of the first nanosheet/nanowire and/or the second nanosheet/nanowire; or wherein the semiconductor device is a p-type device, and a highest energy level of a valence band of the third nanosheet/nanowire is lower than a lowest energy level of a valence band of the first nanosheet/nanowire and/or the second nanosheet/nanowire.

7. The semiconductor device according to claim 4, wherein the first nanosheet/nanowire and the second nanosheet/nanowire comprise Si, and the third nanosheet/nanowire comprises SiGe or Ge.

8. The semiconductor device according to 6 claim 4, wherein the channel portion further comprises a connection portion, and the connection portion connects an end of the first nanosheet/nanowire with a corresponding end of the second nanosheet/nanowire, such that the first nanosheet/nanowire, the second nanosheet/nanowire and the connection portion together surround the third nanosheet/nanowire, and peripheral walls of the first nanosheet/nanowire, the second nanosheet/nanowire and the connection portion form the periphery of the channel portion.

9. The semiconductor device according to claim 8, wherein the connection portion comprises the same material as the first nanosheet/nanowire and/or the second nanosheet/nanowire.

10. The semiconductor device according to claim 4, wherein the first nanosheet/nanowire and the second nanosheet/nanowire have a substantially same first thickness, and the third nanosheet/nanowire has a second thickness.

11. The semiconductor device according to claim 1, wherein at least a part of the gate stack close to the channel portion is substantially coplanar with the channel portion.

12. The semiconductor device according to claim 1, wherein the curved nanosheet/nanowire has a substantially uniform thickness.

13. The semiconductor device according to claim 1, wherein a size of the source/drain portions in the lateral direction with respect to the substrate is greater than a size of the channel portion in corresponding direction.

14. The semiconductor device according to claim 1, wherein the channel portion presents an inwardly concaved C shape on each of two sides in the lateral direction with respect to the substrate.

15. The semiconductor device according to claim 1, further comprising:
a first semiconductor layer and a second semiconductor layer that are respectively located at the upper end and the lower end of the channel portion with respect to the substrate, wherein the source/drain portions are respectively arranged in the first semiconductor layer and the second semiconductor layer.

16. The semiconductor device according to claim 15, wherein the source/drain portions are a doped region formed in a part of the first semiconductor layer on a side of an opening of the C shape and a doped region formed in a part of the second semiconductor layer on a side of the opening of the C shape, respectively.

17. The semiconductor device according to claim 16, wherein there are doping concentration interfaces, that are in a substantially vertical direction with respect to the substrate, between the source/drain portions and other parts of the first semiconductor layer and the second semiconductor layer.

18. The semiconductor device according to claim 17, wherein the doping concentration interface between one of the source/drain portions at the upper end and the other parts of the first semiconductor layer in the vertical direction is substantially aligned with the doping concentration interface between one of the source/drain portions at the lower end and the other parts of the second semiconductor layer in the vertical direction.

19. The semiconductor device according to claim 16, wherein at least a part of the periphery of the gate stack extends along a corresponding periphery of the first semiconductor layer at the upper end of the channel portion.

20. The semiconductor device according to claim 19, wherein a gate conductor layer of the gate stack further comprises a part that extends beyond the periphery of the first semiconductor layer in the lateral direction with respect to the substrate to be used as a pad.

21. The semiconductor device according to claim 15, further comprising:
dielectric layers that are respectively located at the upper end and the lower end of the channel portion with respect to the substrate, and respectively surround at least a part of a periphery of each of the first semiconductor layer and the second semiconductor layer, wherein the dielectric layers are substantially coplanar with the first semiconductor layer or the second semiconductor layer, respectively.

22. The semiconductor device according to claim 21, wherein at least a part of the periphery of the gate stack extends along corresponding peripheries of both the dielectric layer and the first semiconductor layer at the upper end of the channel portion.

23. The semiconductor device according to claim 22, wherein a gate conductor layer of the gate stack further comprises a part that extends beyond the peripheries of both the dielectric layer and the first semiconductor layer at the upper end of the channel portion in the lateral direction with respect to the substrate to be used as a pad.

24. The semiconductor device according to claim 15, wherein at least an upper part of a peripheral wall of the second semiconductor layer at the lower end of the channel portion is substantially aligned with a peripheral wall of the first semiconductor layer at the upper end of the channel portion.

25. The semiconductor device according to claim 1, wherein the curved nanosheet/nanowire contains a single crystal material.

26. The semiconductor device according to claim 1, wherein a plurality of the semiconductor devices are provided on the substrate, and the C shapes of at least one pair of the semiconductor devices are opposite to each other.

27. The semiconductor device according to claim 26, wherein channel portions of the pair of the semiconductor devices are substantially coplanar.

28. The semiconductor device according to claim 27, wherein source/drain portions of the pair of the semiconductor devices at the upper end are substantially coplanar, and source/drain portions of the pair of the semiconductor devices at the lower end are substantially coplanar.

29. The semiconductor device according to claim 26, wherein the C shapes of the pair of the semiconductor devices are symmetrical with each other.

30. The semiconductor device according to claim 1, wherein gate lengths of the gate stacks at two opposite sides of the C-shaped curved nanosheet/nanowire are substantially equal.

31. A method of manufacturing a semiconductor, comprising:
providing a stack of a first material layer, a second material layer and a third material layer;
patterning the stack into a ridge-like structure, wherein the ridge-like structure comprises a first side and a second side that are opposite to each other, and a third side and a fourth side that are opposite to each other;
concaving a sidewall of the second material layer laterally with respect to a sidewall of the first material layer and a sidewall of the third material layer on the third side and the fourth side, so as to form a first concave portion;
forming a first position retaining layer in the first concave portion;
concaving a sidewall of the second material layer laterally with respect to a sidewall of the first material layer and a sidewall of the third material layer on the first side and the second side, so as to form a second concave portion;
forming at least a first channel layer on a surface of the second material layer exposed by the second concave portion;
forming a second position retaining layer in a remaining space of the second concave portion;
forming source/drain portions in the first material layer and the third material layer;
forming a strip-like opening in the ridge-like structure, so as to divide the ridge-like structure into two parts respectively located on the first side and the second side;
removing the second material layer by the opening to expose the first channel layer, so as to define a third concave portion;
forming a third position retaining layer in the third concave portion;
forming an isolation layer on the substrate, wherein a top surface of the isolation layer is not lower than a top surface of the first material layer and not higher than a bottom surface of the third material layer;
removing the first position retaining layer, the second position retaining layer and the third position retaining layer; and
forming a gate stack surrounding the channel layer on the isolation layer, wherein the gate stack comprises parts embedded into spaces left due to the removal of the first position retaining layer, the second position retaining layer and the third position retaining layer.

32. The method according to claim 31, wherein after defining the third concave portion and before forming the third position retaining layer, the method further comprises:
forming at least a second channel layer on a surface of the first channel layer exposed by the third concave portion.

33. The method according to claim 31, wherein forming at least a first channel layer on a surface of the second material layer exposed by the second concave portion comprises:
forming the first channel layer, a second channel layer and a third channel layer in sequence by epitaxial growth.

34. The method according to claim 32,
wherein forming at least a first channel layer on a surface of the second material layer exposed by the second concave portion comprises: forming the first channel layer by epitaxial growth;
wherein forming at least a second channel layer on a surface of the first channel layer exposed by the third concave portion comprises: forming the second channel layer and a third channel layer in sequence by epitaxial growth.

35. The method according to claim 34, further comprising: etching back the first channel layer, the first material layer and the third material layer by the third concave portion.

36. The method according to claim 35, wherein the first channel layer is formed with a sum of a first thickness and a second thickness, an amount of the etch back is the second thickness, the second channel layer is formed with the second thickness, and the third channel layer is formed with the first thickness.

37. The method according to claim 33, wherein at least one of the following characteristics is satisfied:
the first channel layer and the third channel layer comprise a material having an improved interface quality with the gate stack, and the second channel layer comprises a material having a high carrier mobility;
the first channel layer and the third channel layer comprise a material having a high carrier mobility, and the second channel layer comprises a material capable of optimizing a carrier distribution; or
for an n-type device, a lowest energy level of a conduction band of the material of the first channel layer and the third channel layer is higher than a lowest energy level of a conduction band of the material of the second channel layer; or for a p-type device, a highest energy level of a valence band of the material of the first channel layer and the third channel layer is lower than a highest energy level of a valence band of the material of the second channel layer.

38. The method according to claim 37, wherein the first channel layer and the second channel layer contain Si, and the third channel layer contains SiGe or Ge.

39. The method according to claim 37, wherein the first channel layer and the second channel layer have a substantially equal first thickness, and the third channel layer has a second thickness.

40. The method according to claim 37,
wherein removing the first position retaining layer, the second position retaining layer and the third position retaining layer comprises: removing the first position retaining layer first;
wherein the method further comprises: forming a fourth channel layer at an end portion of the first channel layer and an end portion of the third channel portion due to the removal of the first position retaining layer, so as to connect exposed end portions of the first channel layer and the third channel layer with each other.

41. The method according to claim 31, wherein the first material layer is an upper part of the substrate, or an epitaxial layer on the substrate.

42. The method according to claim 31, wherein the second material layer has etching selectivity with respect to the first material layer and the third material layer.

43. The method according to claim 31, wherein a sidewall of the second material layer is concaved through isotropic etching.

44. The method according to claim 31, wherein forming the channel layer comprises selective epitaxial growth.

45. The method according to claim 31, wherein forming the source/drain portions comprises:
forming a dopant source layer on a sidewall of the ridge-like structure; and
driving a dopant in the dopant source layer into the first material layer and the third material layer.

46. The method according to claim 31, wherein after forming the source/drain portions and before forming the opening, the method further comprises:
etching back the first material layer and the third material layer, so that the sidewall of the first material layer and the sidewall of the third material layer are concaved laterally; and
forming a dielectric layer in spaces that are left due to the lateral concave of the first material layer and the third material layer.

47. The method according to claim 31, wherein after forming the third position retaining layer, the method further comprises:
etching back the first material layer and the third material layer by the opening, so that the sidewall of the first material layer and the sidewall of the third material layer are concaved laterally; and
forming a dielectric layer in spaces that are left due to the lateral concave of the first material layer and the third material layer.

48. The method according to claim 31, wherein after defining the second concave portion and before forming the first channel layer, the method further comprises:
etching back an exposed surface of the ridge-like structure so that a thickness of the ridge-like structure is substantially equal to a thickness of the first channel layer to be formed.

49. An electronic apparatus, comprising the semiconductor device according to claim 1.

50. The electronic apparatus according to claim 49, comprising a smartphone, a computer, a tablet computer, a wearable smart apparatus, or a portable power supply.
